(19) United States
(12) Patent Application Publication
(10) Pub. No.: US 2026/0114134 A1
(43) Pub. Date: Apr. 23, 2026

(54) Display Device, Electronic Device Including the Same, and Method of Manufacturing Display Device

(71) Applicant: Samsung Display Co., Ltd., Yongin-si (KR)

(72) Inventors: Han Bit Kim, Yongin-si (KR); Doo Na Kim, Yongin-si (KR); Ji Yeong Shin, Yongin-si (KR); Chang Ho Yi, Yongin-si (KR); Yu Gwang Jeong, Yongin-si (KR); Sang Gun Choi, Yongin-si (KR)

(73) Assignee: Samsung Display Co., Ltd., Yongin-si (KR)

(21) Appl. No.: 19/229,285

(22) Filed: Jun. 5, 2025

(30) Foreign Application Priority Data
Oct. 17, 2024 (KR) 10-2024-0142145

(51) Int. Cl. H10K 59/123; H10K 59/12

(52) U.S. Cl. CPC H10K 59/123; H10K 59/1201

(57) ABSTRACT

A display device includes a substrate, a lower pattern disposed on the substrate, a lower insulating layer disposed on the lower pattern and an upper insulating layer disposed on the lower insulating layer. The display device also defines a contact hole penetrating the lower insulating layer and the upper insulating layer to expose a portion of the lower pattern. A protective film is disposed inside the contact hole and covers a side surface of the lower insulating layer. Additionally, an upper pattern is disposed on the upper insulating layer and the protective film and connected to the lower pattern through the contact hole.

### CROSS-REFERENCE TO RELATED APPLICATION

This application claims priority from Korean Patent Application No. 10-2024-0142145 filed on Oct. 17, 2024, the disclosure of which is incorporated by reference herein in its entirety.

### BACKGROUND

### 1. Technical Field

The present disclosure relates to a display device, an electronic device including the same, and a method of manufacturing a display device.

### 2. Description of the Related Art

With the advance of our information-oriented society, there is increasing demand for display devices that are capable of displaying images in various ways. For example, a display device may be included in various electronic devices and may be used as a display screen for such electronic devices. As part of this trend, various display devices that incorporate a light emitting display device are under development. Such light emitting display devices may include pixels that incorporate light emitting elements.

### BRIEF SUMMARY

Aspects of the present disclosure provide a display device capable of preventing a contact defect that may occur in a contact hole, an electronic device that includes such a display device, and in display devices fabricated through a method of manufacturing the display device.

The above and other aspects of the present disclosure will become more apparent to one of ordinary skill in the art to which the present disclosure pertains by referencing the detailed description of the present disclosure given below.

According to one aspect, the present disclosure relates to a display device. In one embodiment, a display device includes a substrate, a lower pattern disposed on the substrate, a lower insulating layer disposed on the lower pattern, an upper insulating layer disposed on the lower insulating layer, a contact hole penetrating the lower insulating layer and the upper insulating layer to expose a portion of the lower pattern, a protective film disposed inside the contact hole and covering a side surface of the lower insulating layer, and an upper pattern disposed on the upper insulating layer and the protective film and connected to the lower pattern through the contact hole.

In some examples, the contact hole may include a first opening formed in the lower insulating layer and a second opening formed in the upper insulating layer, and a width of the second opening may be greater than a width of the first opening.

In some examples, the upper insulating layer and the protective film may be spaced apart from each other.

In some examples, the upper pattern may have a step-shaped cross-section on a boundary portion between the lower insulating layer and the upper insulating layer.

In some examples, the upper insulating layer and the protective film may be connected continuously.

In some examples, the upper insulating layer and the protective film may be integral.

In some examples, the upper insulating layer and the protective film may contain a same material.

In some examples, a thickness of the protective film may be smaller than a thickness of the upper insulating layer.

In some examples, the upper pattern may fill at least a portion of the contact hole and may be in contact with the lower pattern at a bottom surface of the contact hole.

In some examples, the lower insulating layer may include a plurality of insulating layers sequentially stacked on the lower pattern, and one and another of the plurality of insulating layers may contain different materials.

In some examples, one of the plurality of insulating layers may contain silicon oxide, and another of the plurality of insulating layers may contain silicon nitride.

In some examples, the protective film may entirely cover side surfaces of the plurality of insulating layers at a sidewall portion of the contact hole and may expose the lower pattern at a bottom portion of the contact hole.

In some examples, the display device may include a circuit layer disposed on the substrate. The circuit layer may include the lower pattern, the lower insulating layer, the upper insulating layer, the contact hole, the protective film, the upper pattern. and a circuit element of a pixel. In still further examples, the display device may include a light emitting element layer disposed on the circuit layer and a light emitting element electrically connected to the circuit element.

According to another aspect of the present disclosure, the present disclosure relates to a method of manufacturing a display device. In one embodiment, a method of manufacturing a display device includes: forming a lower pattern and a lower insulating layer covering the lower pattern on a substrate, forming a first opening exposing a portion of the lower pattern by etching the lower insulating layer, forming an insulating film on the lower pattern and the lower insulating layer, forming a protective film covering a side surface of the lower insulating layer exposed through the first opening and an upper insulating layer disposed on the lower insulating layer and including a second opening communicating with the first opening, by etching the insulating film, and forming an upper pattern connected to the lower pattern on the portion of the lower pattern, the protective film, and the upper insulating layer.

In some examples, the etching of the insulating film may include disposing a mask pattern including an opening exposing the first opening on the insulating film, and etching a portion of the insulating film not covered by the mask pattern.

In some examples, the opening of the mask pattern may have a width greater than a width of the first opening and exposes the first opening and a portion of the insulating film positioned around the first opening.

In some examples, a width of the second opening may be larger than the width of the first opening, and the protective film and the upper insulating layer may be formed to be spaced apart from each other.

In some examples, the etching of the insulating film may include removing a portion of the insulating film covering the lower pattern by full-surface anisotropic dry etching.

In some examples, the method may further include, before the forming of the upper pattern, performing wet etching using a buffered oxide etchant in a state where the side surface of the lower insulating layer is covered with the protective film.

According to yet another aspect, the present disclosure relates to an electronic device. In one embodiment, an electronic device includes a display device and a display device housing configured to accommodate the display device. The display device includes a substrate, a lower pattern disposed on the substrate, a lower insulating layer disposed on the lower pattern, an upper insulating layer disposed on the lower insulating layer, a contact hole penetrating the lower insulating layer and the upper insulating layer to expose a portion of the lower pattern, a protective film disposed inside the contact hole and covering a side surface of the lower insulating layer, and an upper pattern disposed on the upper insulating layer and the protective film and connected to the lower pattern through the contact hole.

According to the display device, the electronic device including the same, and the method of manufacturing the display device as contemplated throughout the present disclosure, it is possible to prevent a contact defect that may occur in the contact hole inside the display device, and to stably connect a lower pattern and an upper pattern by the contact hole. Accordingly, the reliability of the display device and the electronic device including the same may be improved.

The advantageous effects of the embodiments of the present disclosure are not limited to the above-described effects and other advantageous effects will become apparent to those skill in the art from the following description.

### BRIEF DESCRIPTION OF THE DRAWINGS

The above and other aspects and features of the present disclosure will become more apparent by reading the following detailed description of non-limiting embodiments thereof, and with reference to the accompanying drawings, in which:

FIG. 1 is a perspective view of a display device according to one embodiment of the present disclosure;

FIG. 2 is a circuit diagram of a pixel according to one embodiment of the present disclosure;

FIG. 3 is a cross-sectional view of a display device according to one embodiment of the present disclosure;

FIG. 4 is a close-up cross-sectional view of a contact hole, and a lower pattern and an upper pattern connected through the contact hole, according to one embodiment of the present disclosure;

FIG. 5 is a cross-sectional view of a contact hole, and a lower pattern and an upper pattern connected through the contact hole, according to one embodiment of the present disclosure;

FIGS. 6 to 13 are close-up cross-sectional views of a portion of a circuit layer in steps of a method of manufacturing a display device according to one embodiment of the present disclosure;

FIGS. 14 to 17 are close-up cross-sectional views of a portion of a circuit layer in steps of a method of manufacturing a display device according to one embodiment of the present disclosure;

FIG. 18 is a perspective view of a head mounted display according to one embodiment of the present disclosure;

FIG. 19 is an exploded perspective view of an example of the head mounted display of FIG. 18; and

FIG. 20 is a perspective view of a head mounted display according to one embodiment of the present disclosure.

### DETAILED DESCRIPTION

The present disclosure will now be described more fully hereinafter with reference to the accompanying drawings. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when an element or a layer is referred to as being “on” another element or layer, it can be directly on the other element or layer, or intervening layers may also be present. Like reference numerals refer to like elements throughout the specification.

It will be understood that, although the terms “first,” “second,” etc. may be used herein to describe various elements, these elements should not be limited by the use of such terms. These terms are only used to distinguish one element from another element in the context within which they are used. For instance, a first element discussed below could be termed a second element instead without departing from the teachings of the present disclosure. Similarly, the second element could also be termed the first element.

Features of any one of the various embodiments of the present disclosure may be partially or entirely combined with other embodiments and may do so in a manner so that the combined features are technically operable with each other. Respective embodiments may be implemented independently of each other or may be implemented together in association with each other.

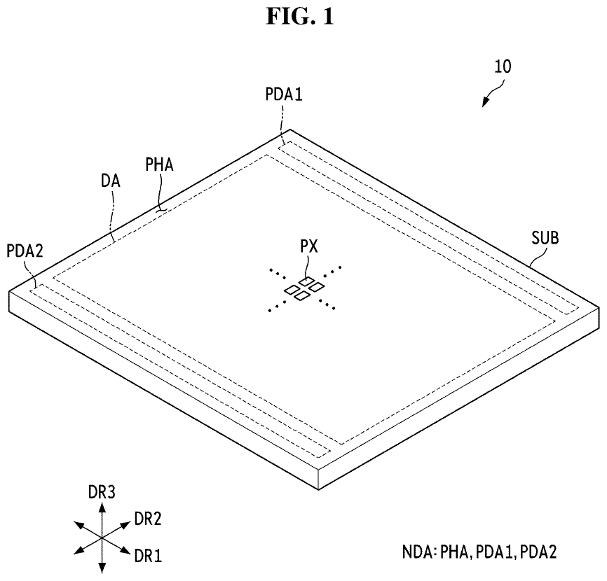

FIG. 1 is a perspective view illustrating a display device according to one embodiment of the present disclosure.

Referring to FIG. 1, a display device 10 is a device for displaying a moving image or a still image, and may be used as a display screen for various electronic devices. For example, the display device 10 may be included in various electronic devices such as televisions, laptop computers, monitors, billboards and Internet of Things (IOT) devices as well as portable electronic devices such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs), and may be used as a display screen for such electronic devices. Additionally, the display device 10 may also be included in other electronic devices such as a virtual reality (VR) device, an augmented reality (AR) device, or the like.

In one embodiment, the display device 10 may be a light emitting display device including a light emitting element. For example, the display device 10 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display using an ultra-small light emitting diode such as a micro or nano light emitting diode (micro LED or nano LED). However, the contemplated display device embodiments are not limited thereto. For example, the display device 10 may be another light emitting display device or another type of display device other than a light emitting display device.

Hereinafter, embodiments in which the display device 10 is an organic light emitting display device will be disclosed. However, the display device 10 according to embodiments is not limited to an organic light emitting display device, and the technical features of embodiments described herein may be applied to other types of display devices.

In one embodiment, the display device 10 is as shown in FIG. 1 and includes a substrate SUB and pixels PX disposed on the substrate SUB.

The substrate SUB may be a base layer for manufacturing or providing the display device 10. The substrate SUB may have a quadrilateral planar shape on a plane defined by a first direction DR1 and a second direction DR2, but is not limited thereto. For example, the substrate SUB may have a polygonal shape other than a quadrilateral shape, a circular shape, an elliptical shape, or an irregular shape when viewed in plan view.

In FIG. 1, the first direction DR1 may refer to a horizontal direction (or vertical direction) of the substrate SUB (or display device 10), and the second direction DR2 may refer to a vertical direction (or horizontal direction) of the substrate SUB. A third direction DR3 may refer to a thickness direction or a height direction of the substrate SUB.

With continued reference to FIG. 1, the substrate SUB of the display device 10 may include a display area DA and a non-display area NDA. The display area DA may be an area in which an image is displayed, and the non-display area NDA may be an area other than the display area DA.

The display area DA may be an area where the pixels PX are disposed. For example, the pixels PX and at least some wires connected to the pixels PX may be disposed in the display area DA. In embodiments described herein, the term “connect” may encompass an electrical connection and/or a physical connection.

The non-display area NDA may be disposed around the display area DA. In one embodiment, the non-display area NDA may include a first pad area PDA1, a second pad area PDA2, and a peripheral area PHA. Wires connected to the pixels PX (e.g., some of the wires extending from the display area DA to the non-display area NDA) and pads may be disposed in the non-display area NDA. In some embodiments, the non-display area NDA may include a driving circuit area in which at least a portion of a driving circuit connected to the pixels PX is disposed.

Although FIG. 1 illustrates an embodiment in which the display device 10 includes the first pad area PDA1 and the second pad area PDA2 disposed on different sides (e.g., an upper side and a lower side, respectively) of the display area DA, the quantity, size and/or position of the pad areas PDA1 and PDA2 is not limited. For example, the display device 10 may include only one of the first pad area PDA1 and the second pad area PDA2, or may include three or more pad areas.

Each of the first pad area PDA1 and the second pad area PDA2 may include one or more pads connected to an external circuit board. Driving signals and driving voltages for driving the pixels PX may be supplied from the circuit board to the display device 10 through the pads.

The peripheral area PHA may be the remaining area of the non-display area NDA excluding the first pad area PDA1 and the second pad area PDA2. The peripheral area PHA may surround the display area DA. In some examples, the peripheral area PHA may include the driving circuit area. In other examples, the peripheral area PHA may be absent the driving circuit area.

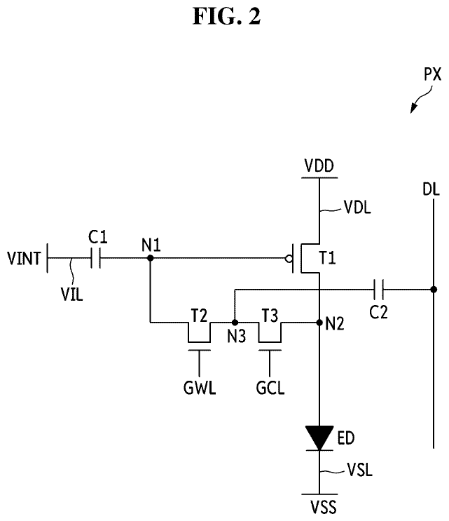

FIG. 2 is an equivalent circuit diagram of a pixel PX according to one embodiment of the present disclosure.

Referring to FIG. 2, the pixel PX may be connected to signal lines including a first scan line GWL, a second scan line GCL, and a data line DL, and power lines including a first voltage line VDL, a second voltage line VSL, and an initialization voltage line VIL (or an initialization signal line). The type and/or quantity of signal lines and power lines connected to the pixel PX may vary depending on the type and/or structure of the pixel PX.

The first scan line GWL and the second scan line GCL may be connected between a scan driving circuit and the pixel PX. The first scan line GWL transmits the first scan signal outputted from the scan driving circuit to the pixel PX. In one embodiment, the first scan line GWL may be a write scan line, and the first scan signal may be a write scan signal. The second scan line GCL transmits the second scan signal outputted from the scan driving circuit to the pixel PX. In one embodiment, the second scan line GCL may be a control scan line, and the second scan signal may be a control scan signal. In some examples, the scan driving circuit may be disposed on a circuit board connected to the display device 10 through signal pads (e.g., scan pads) disposed on the substrate SUB or disposed in at least one of the first pad area PDA1 or the second pad area PDA2.

The data line DL may be connected between the data driving circuit and the pixel PX. The data line DL transmits the data voltage outputted from the data driving circuit to the pixel PX. In some examples, the data driving circuit may be disposed on a circuit board connected to the display device 10 through signal pads (e.g., data pads) disposed on the substrate SUB or disposed in at least one of the first pad area PDA1 or the second pad area PDA2.

The first voltage line VDL and the second voltage line VSL may be connected between a power supply circuit and the pixel PX. The first voltage line VDL and the second voltage line VSL transmit a first driving voltage VDD and a second driving voltage VSS outputted from the power supply circuit to the pixel PX. In one embodiment, the first driving voltage VDD may be a high-potential pixel voltage, and the second driving voltage VSS may be a low-potential pixel voltage. In some examples, the power supply circuit may be disposed on the circuit board connected to the display device 10 through the power pads disposed in at least one of the first pad area PDA1 or the second pad area PDA2.

The initialization voltage line VIL may be connected between the power supply circuit or the scan driving circuit and the pixel PX. The initialization voltage line VIL transmits an initialization voltage VINT outputted from the power supply circuit or the scan driving circuit to the pixel PX.

The pixel PX may include a light emitting element ED and a pixel circuit electrically connected to the light emitting element ED.

The light emitting element ED may be connected between the pixel circuit and the second voltage line VSL. For example, the first electrode (e.g., anode electrode) of the light emitting element ED may be connected to the pixel circuit through a second node N2, and the second electrode (e.g., cathode electrode) of the light emitting element ED may be connected to the second voltage line VSL.

The light emitting element ED may be a light source of the pixel PX and may emit light corresponding to the driving current supplied from the pixel circuit. In some examples, the light emitting element ED may be an organic light emitting diode, but is not limited thereto. For example, the light emitting element ED may be an inorganic light emitting element, a quantum dot light emitting element, or another type of light emitting element.

The pixel circuit may be connected between the first voltage line VDL and the light emitting element ED. Additionally, the pixel circuit may also be connected to the first scan line GWL, the second scan line GCL, the data line DL, and the initialization voltage line VIL.

The pixel circuit may include circuit elements including transistors and capacitors. In some examples, the pixel circuit may be configured such that the pixel PX emits light with a uniform luminance in response to the data voltage of each grayscale, and thus may include a plurality of transistors and at least one capacitor. In some examples, the pixel circuit may include first, second, and third transistors T1, T2, and T3, and first and second capacitors C1 and C2. The type and/or structure of the pixel circuit may be modified in various ways to suit different embodiments and examples thereof.

In one embodiment, the pixel circuit may include at least one P-type transistor and at least one N-type transistor. For example, the first transistor T1 may be a P-type transistor, and the second and third transistors T2 and T3 may be N-type transistors. In some examples, the P-type transistor and the N-type transistor may include active layers formed of different materials. For example, the active layer of a P-type transistor may include polysilicon, and the active layer of an N-type transistor may include an oxide semiconductor. However, the transistor types are not limited thereto. For example, the first, second and third transistors T1, T2, and T3 may be formed of transistors of the same type (e.g., P-type or N-type transistors).

Each of the first, second and third transistors T1, T2, and T3 may include a gate electrode, a source electrode (or a source region functioning as a source electrode), and a drain electrode (or a drain region functioning as a drain electrode). The source electrode and the drain electrode of each of the first, second, and third transistors T1, T2, and T3 may be the first electrode and the second electrode, respectively. Depending on the voltage applied to both ends of each of the first, second, and third transistors T1, T2, and T3 or the type (e.g., P-type or N-type transistor) of each of the first, second, and third transistors T1, T2, and T3, one of the first electrode and the second electrode of each of the first, second, and third transistors T1, T2, and T3 may be a source electrode, and the other may be a drain electrode.

The gate electrode of the first transistor T1 may be connected to a first node N1, the source electrode thereof may be connected to the first voltage line VDL, and the drain electrode thereof may be connected to the second node N2. The second node N2 may be a node to which the first electrode (e.g., anode electrode) of the light emitting element ED is connected. The first transistor T1 may control the driving current flowing through the light emitting element ED according to the voltage of the first node N1.

The gate electrode of the second transistor T2 may be connected to the first scan line GWL, the source electrode thereof may be connected to the first node N1, and the drain electrode thereof may be connected to a third node N3. The second transistor T2 may be turned on by the first scan signal of the gate-on voltage applied to the first scan line GWL to electrically connect the first node N1 to the third node N3.

The first node N1 may be connected to a first electrode of the first capacitor C1. The voltage of the first node N1 may be initialized by the initialization voltage VINT applied to the initialization voltage line VIL connected to a second electrode of the first capacitor C1.

The third node N3 may be connected to the first electrode of the second capacitor C2. The voltage of the third node N3 may be changed to a voltage corresponding to the data voltage applied to the data line DL connected to the second electrode of the second capacitor C2.

The gate electrode of the third transistor T3 may be connected to the second scan line GCL, the source electrode thereof may be connected to the third node N3, and the drain electrode thereof may be connected to the second node N2. The third transistor T3 may be turned on by the second scan signal of the gate-on voltage applied to the second scan line GCL to electrically connect the third node N3 to the second node N2.

The first capacitor C1 may be connected between the first node N1 and the initialization voltage line VIL. For example, the first electrode of the first capacitor C1 may be connected to the first node N1, and the second electrode of the first capacitor C1 may be connected to the initialization voltage line VIL, so that the potential difference between the first node N1 and the initialization voltage line VIL may be maintained. The voltage of the first node N1 may be initialized by the initialization voltage VINT applied to the initialization voltage line VIL.

The second capacitor C2 may be connected between the third node N3 and the data line DL. For example, the first electrode of the second capacitor C2 may be connected to the third node N3 and the second electrode of the second capacitor C2 may be connected to the data line DL so that the potential difference between the third node N3 and the data line DL may be maintained. The voltage of the third node N3 may be changed to a voltage corresponding to the data voltage applied to the data line DL.

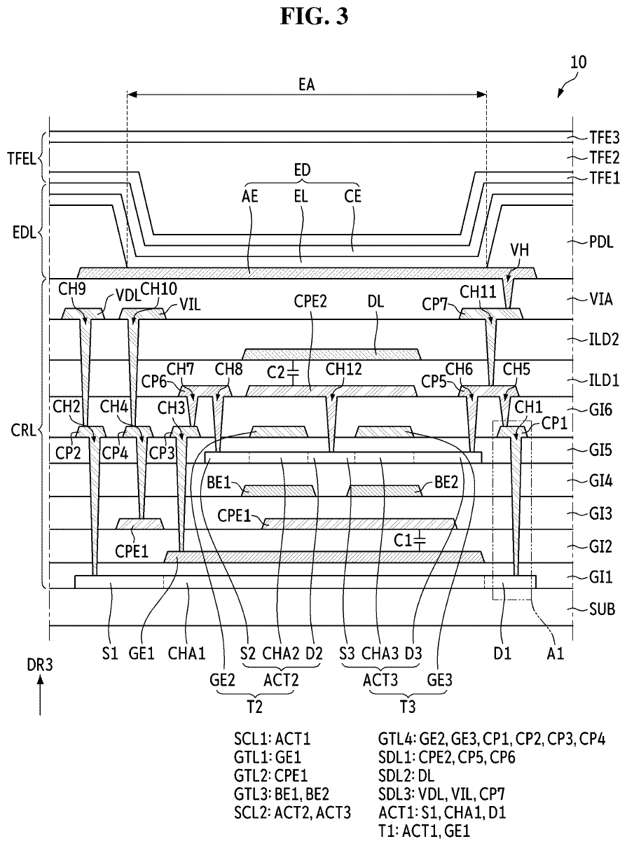

FIG. 3 is a cross-sectional view of a display device according to one embodiment of the present disclosure. Specifically, FIG. 3 illustrates a schematic cross section of a portion of the display device 10 in which the pixel PX is disposed. For example, the cross-section may represent a portion of the display device 10 that is one pixel area positioned in the display area DA.

Referring to FIG. 3, the display device 10 includes the substrate SUB and a circuit layer CRL disposed on the substrate SUB. In some examples, the display device 10 may be a light emitting display device including the light emitting element ED, and may also include a light emitting element layer EDL and an encapsulation layer TFEL. In some examples, the circuit layer CRL, the light emitting element layer EDL, and the encapsulation layer TFEL may be sequentially disposed on the substrate SUB along the third direction DR3.

FIG. 3 illustrates a structure in which the first transistor T1 of the circuit layer CRL is disposed directly on the substrate SUB, but the contemplated embodiments are not limited thereto. For example, a buffer layer (or barrier layer) may be formed on the substrate SUB, and the circuit layer CRL may be disposed on the buffer layer.

The substrate SUB may be a base layer for forming the display device 10. For example, the substrate SUB may form a support for a display panel including the pixels PX.

In some embodiments, the substrate SUB may be a substrate having rigid characteristics and including an insulating material such as glass. In some examples, the substrate SUB may include an insulating material such as polymer resin and may be a flexible substrate capable of transformation such as bending, folding, or rolling. However, the contemplated substrates are not limited thereto, and substrates including other insulating materials are also contemplated. In other embodiments, the substrate SUB may be a semiconductor substrate, and the substrate SUB and the pixel circuit may be formed of a semiconductor circuit substrate including a complementary metal-oxide semiconductor (CMOS) circuit formed using a semiconductor process.

With continued reference to FIG. 3, the circuit layer CRL is disposed on the substrate SUB (or buffer layer). The circuit layer CRL may include circuit elements included in each of the pixels PX (e.g., circuit elements included in each pixel circuit) and wires connected to the pixels PX. For example, the circuit layer CRL may include the first, second, and third transistors T1, T2, and T3, the first and second capacitors C1 and C2, the first scan line GWL, the second scan line GCL, the data line DL, the first voltage line VDL, the second voltage line VSL, and the initialization voltage line VIL, each shown in FIG. 2.

The circuit layer CRL may include at least one semiconductor layer, a plurality of conductive layers, and a plurality of insulating layers disposed on the substrate SUB. The semiconductor layer of the circuit layer CRL may include active layers of transistors disposed within the circuit layer CRL. The conductive layers of the circuit layer CRL may include conductive patterns included in circuit elements (e.g., transistors and capacitors) disposed within the circuit layer CRL, or connected to the circuit elements. The conductive patterns may include electrodes of circuit elements, connection patterns (e.g., bridge patterns) connected to the circuit elements, and/or wires. The insulating layers of the circuit layer CRL may be disposed between the semiconductor layer and the conductive layers of the circuit layer CRL.

In one embodiment, the circuit layer CRL may include a plurality of semiconductor layers. For example, the circuit layer CRL may include a first semiconductor layer SCL1 including a first active layer ACT1 of the first transistor T1, and a second semiconductor layer SCL2 including second and third active layers ACT2 and ACT3 of the second and third transistors T2 and T3, respectively. The first semiconductor layer SCL1 and the second semiconductor layer SCL2 may be disposed in different layers on the substrate SUB. Accordingly, the integration density of the circuit layer CRL may be increased and the design of the circuit layer CRL may be optimized. For example, even in a high-resolution display device that includes the pixels PX where the pixels are small in size (e.g., cover a narrow surface area), the circuit elements of the pixels PX may be appropriately disposed within each limited pixel area. In some embodiments, the active layers disposed in the different semiconductor layers may include different semiconductor materials. For example, the first active layer ACT1 may include a first semiconductor material, and the second and third active layers ACT2 and ACT3 may include a second semiconductor material different from the first semiconductor material. However, the contemplated embodiments are not limited thereto. For example, by disposing active layers that include the same semiconductor material in different layers, a design space for forming transistors may be provided.

In another embodiment, the pixels PX may include two or more transistors of the same type, and the semiconductor layers of the transistors may be formed simultaneously in the same layer. In this arrangement, the number of semiconductor layers, conductive layers, and/or insulating layers included in the circuit layer CRL may be reduced so that the manufacturing process of the circuit layer CRL may be streamlined, and the thickness of the circuit layer CRL may be reduced. Additionally, a depth dimension of at least some of the contact holes may be reduced.

FIG. 3 illustrates an embodiment in which the circuit layer CRL includes the first semiconductor layer SCL1 and the second semiconductor layer SCL2. Accordingly, the display device 10, which may be a high-resolution display device, may be easily manufactured.

In some embodiments, including the display device 10 as illustrated in FIG. 3, the conductive layers of the circuit layer CRL may include a first conductive layer GTL1, a second conductive layer GTL2, a third conductive layer GTL3, a fourth conductive layer GTL4, a fifth conductive layer SDL1, a sixth conductive layer SDL2, and a seventh conductive layer SDL3.

In some embodiments, again including the display device 10 as illustrated in FIG. 3, the insulating layers of the circuit layer CRL may include a first insulating layer GI1, a second insulating layer GI2, a third insulating layer GI3, a fourth insulating layer GI4, a fifth insulating layer GI5, a sixth insulating layer GI6, a seventh insulating layer ILD1, an eighth insulating layer ILD2, and a ninth insulating layer VIA. As shown in FIG. 3, these layers may be sequentially disposed on the substrate SUB along the third direction DR3.

The structure of the circuit layer CRL may vary depending on the embodiment. For example, one or more of the number, type and/or position of semiconductor layers, conductive layers, and insulating layers included in the circuit layer CRL, and/or one or more of the number, type and/or shape, or the like of patterns included in the semiconductor layers, the conductive layers, and the insulating layers may vary from that shown in FIG. 3. For example, a particular structural arrangement of the circuit layer CRL may vary to suit the design structure of a specific arrangement of pixel circuits and wires.

With continued reference to FIG. 3, the first semiconductor layer SCL1 may be disposed on the substrate SUB (or buffer layer). The first semiconductor layer SCL1 may include semiconductor patterns containing a semiconductor material (e.g., polysilicon, amorphous silicon, oxide semiconductor, or other semiconductor materials). In some examples, the semiconductor patterns of the first semiconductor layer SCL1 may include polysilicon. In some examples, the first semiconductor layer SCL1 may include the first active layer ACT1 included in the first transistor T1 of the pixel PX.

The first active layer ACT1 may include a first channel region CHA1, a first source region S1, and a first drain region D1. The first channel region CHA1 may overlap a first gate electrode GE1 included in the first transistor T1. The first channel region CHA1 may form a channel in response to a voltage applied to the first gate electrode GE1. The first source region S1 and the first drain region D1 may be disposed on respective sides of the first channel region CHA1. The first source region S1 and the first drain region D1 may have higher conductivity than the first channel region CHA1. For example, the carrier concentration of the first source region S1 and the first drain region D1 may be higher than the carrier concentration of the first channel region CHA1.

In some embodiments, the first source region S1 may be electrically connected to the first voltage line VDL through the second conductive pattern CP2 (or the first source electrode included in the first transistor T1). The first drain region D1 may be electrically connected to a first electrode AE of the light emitting element ED and a third drain region D3 of the third transistor T3 through at least one conductive pattern including a first conductive pattern CP1 (or the first drain electrode included in the first transistor T1).

With continued reference to FIG. 3, the first insulating layer GI1 may be disposed on the substrate SUB and the first semiconductor layer SCL1 and may cover the semiconductor patterns of the first semiconductor layer SCL1. In some examples, the first insulating layer GI1 may cover the first active layer ACT1. In some examples, the first insulating layer GI1 may cover a lower pattern LPT.

The first conductive layer GTL1 may be disposed on the first insulating layer GI1. The first conductive layer GTL1 may include conductive patterns including a conductive material. For example, the first conductive layer GTL1 may include the first gate electrode GE1 included in the first transistor T1 of the pixel PX. In one embodiment, the first gate electrode GE1 may be formed integrally with the first electrode of the first capacitor C1. For example, the first gate electrode GE1 may overlap a first capacitor electrode CPE1, and the first capacitor C1 may be formed by the first gate electrode GE1 and the first capacitor electrode CPE1. The first gate electrode GE1 and the first capacitor electrode CPE1 may form the first electrode and the second electrode of the first capacitor C1, respectively.

The second insulating layer GI2 may be disposed on the first insulating layer GI1 and the first conductive layer GTL1 and may cover the conductive patterns of the first conductive layer GTL1. For example, the second insulating layer GI2 may cover the first gate electrode GE1.

The second conductive layer GTL2 may be disposed on the second insulating layer GI2. The second conductive layer GTL2 may include conductive patterns including a conductive material. For example, the second conductive layer GTL2 may include the first capacitor electrode CPE1 overlapping the first gate electrode GE1 of the pixel PX. The first capacitor electrode CPE1 illustrated as being separated into two patterns in FIG. 3 may be a single electrode that is connected when viewed in plan view.

The third insulating layer GI3 may be disposed on the second insulating layer GI2 and the second conductive layer GTL2 and may cover the conductive patterns of the second conductive layer GTL2. For example, the third insulating layer GI3 may cover the first capacitor electrode CPE1.

The third conductive layer GTL3 may be disposed on the third insulating layer GI3. The third conductive layer GTL3 may include conductive patterns including a conductive material. For example, the third conductive layer GTL3 may include a first bottom electrode BE1 and a second bottom electrode BE2 that overlap the second and third active layers ACT2 and ACT3 of the second and third transistors T2 and T3 of the pixel PX associated with FIG. 3. The first bottom electrode BE1 may overlap a second channel region CHA2 of the second active layer ACT2, and the second bottom electrode BE2 may overlap a third channel region CHA3 of the third active layer ACT3. In some examples, the first bottom electrode BE1 may be electrically connected to the second gate electrode GE2 of the second transistor T2 (not shown). In some examples, the second bottom electrode BE2 may be electrically connected to the third gate electrode GE3 of the third transistor T3 (not shown). However, the arrangements of the first bottom electrode BE1, the second bottom electrode BE2, and the third conductive layer GTL3 more generally, are not limited to the described examples.

The fourth insulating layer GI4 may be disposed on the third insulating layer GI3 and the third conductive layer GTL3 and may cover the conductive patterns of the third conductive layer GTL3. For example, the fourth insulating layer GI4 may cover the first bottom electrode BE1 and the second bottom electrode BE2.

The second semiconductor layer SCL2 may be disposed on the fourth insulating layer GI4. The second semiconductor layer SCL2 may include semiconductor patterns containing a semiconductor material (e.g., polysilicon, amorphous silicon, oxide semiconductor, or other semiconductor materials). In some examples, the semiconductor patterns of the second semiconductor layer SCL2 may include an oxide semiconductor. In some examples, the second semiconductor layer SCL2 may include the second active layer ACT2 and the third active layer ACT3 included in the respective second transistor T2 and the third transistor T3 of the pixel PX associated with FIG. 3. In some examples, the second active layer ACT2 and the third active layer ACT3 may be formed integrally. For example, a second drain region D2 and a third source region S3 may be part of one integral structure.

In some examples, the second active layer ACT2 may include the second channel region CHA2, a second source region S2, and the second drain region D2. The second channel region CHA2 may overlap the second gate electrode GE2 included in the second transistor T2. The second channel region CHA2 may form a channel in response to a voltage applied to the second gate electrode GE2. The second source region S2 and the second drain region D2 may be disposed on respective sides of the second channel region CHA2. The second source region S2 and the second drain region D2 may have higher conductivity than the second channel region CHA2.

In some examples, the third active layer ACT3 may include the third channel region CHA3, the third source region S3, and the third drain region D3. The third channel region CHA3 may overlap the third gate electrode GE3 included in the third transistor T3. The third channel region CHA3 may form a channel in response to a voltage applied to the third gate electrode GE3. The third source region S3 and the third drain region D3 may be disposed on respective sides of the third channel region CHA3. The third source region S3 and the third drain region D3 may have higher conductivity than the third channel region CHA3.

In some embodiments, the second source region S2 may be electrically connected to the first gate electrode GE1 through a sixth conductive pattern CP6 (or the second source electrode included in the second transistor T2). The second drain region D2 may be integral with the third source region S3. The second drain region D2 and the third source region S3 may be electrically connected to a second capacitor electrode CPE2 (or the second drain electrode included in the second transistor T2 and the third source electrode included in the third transistor T3). The third drain region D3 may be electrically connected to the first drain region D1 and the first electrode AE of the light emitting element ED through at least one conductive pattern including a fifth conductive pattern CP5 (or the third drain electrode included in the third transistor T3).

The fifth insulating layer GI5 may be disposed on the fourth insulating layer GI4 and the second semiconductor layer SCL2 and may cover the semiconductor patterns of the second semiconductor layer SCL2. For example, the fifth insulating layer GI5 may cover the second active layer ACT2 and the third active layer ACT3.

The fourth conductive layer GTL4 may be disposed on the fifth insulating layer GI5. The fourth conductive layer GTL4 may include conductive patterns including a conductive material. For example, the fourth conductive layer GTL4 may include the second and third gate electrodes GE2 and GE3 included in the second and third transistors T2 and T3 of the pixel PX associated with FIG. 3. The second gate electrode GE2 may be electrically connected to the first scan line GWL of FIG. 2. In some examples, the second gate electrode GE2 and the first scan line GWL may be formed integrally, but are not limited to such an arrangement. The third gate electrode GE3 may be electrically connected to the second scan line GCL of FIG. 2. In some examples, the third gate electrode GE3 and the second scan line GCL may be formed integrally, but are not limited to such an arrangement.

In some embodiments, the fourth conductive layer GTL4 may include at least one conductive pattern in the form of an electrode in addition to the second and third gate electrodes GE2 and GE3. The conductive pattern may constitute at least one circuit element included in the pixel PX associated with FIG. 3 or a connection pattern electrically connected to the at least one circuit element. For example, the fourth conductive layer GTL4 may include the first, second, third and fourth conductive patterns CP1, CP2, CP3, and CP4 of the pixel PX.

The first conductive pattern CP1 may be electrically connected to a region of the first active layer ACT1 by penetrating a plurality of insulating layers disposed between the first semiconductor layer SCL1 and the fourth conductive layer GTL4. For example, the first conductive pattern CP1 may be electrically connected to the first drain region D1 through a first contact hole CH1, e.g., through a contact along a wall defining an opening within the contact hole or along any part of the contact hole where the contact hole is solid, where the first contact hole CH1 is formed in the first insulating layer GI1, the second insulating layer GI2, the third insulating layer GI3, the fourth insulating layer GI4, and the fifth insulating layer GI5 to expose a portion of the first drain region D1. For example, the first conductive pattern CP1 may be in direct contact with the first drain region D1 exposed by the first contact hole CH1. In some examples, the first conductive pattern CP1 may be a drain electrode of the first transistor T1 and may be considered as a component included in the first transistor T1. Additionally, it should be appreciated that electrical connections made through other contact holes as described throughout the present disclosure may be accomplished in a similar manner to the examples set forth above.

The second conductive pattern CP2 may be electrically connected to another region of the first active layer ACT1 by penetrating a plurality of insulating layers disposed between the first semiconductor layer SCL1 and the fourth conductive layer GTL4. For example, the second conductive pattern CP2 may be electrically connected to the first source region S1 through a second contact hole CH2, where the second contact hole CH2 is formed in the first insulating layer GI1, the second insulating layer GI2, the third insulating layer GI3, the fourth insulating layer GI4, and the fifth insulating layer GI5 to expose a portion of the first source region S1. In some examples, the second conductive pattern CP2 may be a source electrode of the first transistor T1 and may be considered as a component included in the first transistor T1.

The third conductive pattern CP3 may be electrically connected to the first gate electrode GE1 by penetrating a plurality of insulating layers disposed between the first conductive layer GTL1 and the fourth conductive layer GTL4. For example, the third conductive pattern CP3 may be electrically connected to the first gate electrode GE1 through a third contact hole CH3 formed in the second insulating layer GI2, the third insulating layer GI3, the fourth insulating layer GI4, and the fifth insulating layer GI5 to expose a portion of the first gate electrode GE1. In one embodiment, the third conductive pattern CP3 may be a connection pattern constituting the first node N1.

The fourth conductive pattern CP4 may be electrically connected to the first capacitor electrode CPE1 by penetrating a plurality of insulating layers disposed between the second conductive layer GTL2 and the fourth conductive layer GTL4. For example, the fourth conductive pattern CP4 may be electrically connected to the first capacitor electrode CPE1 through a fourth contact hole CH4, where the fourth contact hole CH4 is formed in the third insulating layer GI3, the fourth insulating layer GI4, and the fifth insulating layer GI5 to expose a portion of the first capacitor electrode CPE1. In some examples, the fourth conductive pattern CP4 may be a connection pattern connecting the first capacitor electrode CPE1 to the initialization voltage line VIL.

The sixth insulating layer GI6 may be disposed on the fifth insulating layer GI5 and the fourth conductive layer GTL4 and may cover the conductive patterns of the fourth conductive layer GTL4. For example, the sixth insulating layer GI6 may cover the second and third gate electrodes GE2 and GE3 and the first, second, third, and fourth conductive patterns CP1, CP2, CP3, and CP4.

The fifth conductive layer SDL1 may be disposed on the sixth insulating layer GI6. The fifth conductive layer SDL1 may include conductive patterns including a conductive material. For example, the fifth conductive layer SDL1 may include the second capacitor electrode CPE2 of the pixel PX associated with FIG. 3. The second capacitor electrode CPE2 overlaps the data line DL (or the second electrode of the second capacitor C2 electrically connected to the data line DL) connected to the pixel PX, and the second capacitor C2 may be formed by the second capacitor electrode CPE2 and the data line DL. In some examples, the second capacitor electrode CPE2 and the data line DL may form the first electrode and the second electrode of the second capacitor C2, respectively.

The second capacitor electrode CPE2 may be electrically connected to a region of the second active layer ACT2 and the third active layer ACT3 by penetrating a plurality of insulating layers disposed between the second semiconductor layer SCL2 and the fifth conductive layer SDL1. For example, the second capacitor electrode CPE2 may be electrically connected to the second drain region D2 and the third source region S3 through a twelfth contact hole CH12, where the twelfth contact hole CH12 is formed in the fifth insulating layer GI5 and the sixth insulating layer GI6 to expose a portion of the second drain region D2 and the third source region S3. In some examples, the second capacitor electrode CPE2 may be the drain electrode of the second transistor T2 and the source electrode of the third transistor T3, and may be considered as a component included in the second transistor T2 and the third transistor T3. For example, the second capacitor C2, the second transistor T2, and the third transistor T3 may share one electrode that is commonly connected to the third node N3.

In some embodiments, the fifth conductive layer SDL1 may include at least one conductive pattern in the form of an electrode in addition to the second capacitor electrode CPE2. The conductive pattern may constitute at least one circuit element included in the pixel PX associated with FIG. 3 or a connection pattern electrically connected to the at least one circuit element. For example, the fifth conductive layer SDL1 may include the fifth and sixth conductive patterns CP5 and CP6 of the pixel PX.

The fifth conductive pattern CP5 may be electrically connected to the first conductive pattern CP1 by penetrating the insulating layer disposed between the fourth conductive layer GTL4 and the fifth conductive layer SDL1. For example, the fifth conductive pattern CP5 may be electrically connected to the first conductive pattern CP1 through a fifth contact hole CH5, where the fifth contact hole CH5 is formed in the sixth insulating layer GI6 to expose a portion of the first conductive pattern CP1. Additionally, the fifth conductive pattern CP5 may be electrically connected to the third active layer ACT3 by penetrating a plurality of insulating layers disposed between the second semiconductor layer SCL2 and the fifth conductive layer SDL1. For example, the fifth conductive pattern CP5 may be electrically connected to the third drain region D3 through a sixth contact hole CH6, where the sixth contact hole CH6 is formed in the fifth insulating layer GI5 and the sixth insulating layer GI6 to expose a portion of the third drain region D3. In some examples, the fifth conductive pattern CP5 may be a drain electrode of the third transistor T3 and may also be considered as a component included in the third transistor T3.

The sixth conductive pattern CP6 may be electrically connected to the third conductive pattern CP3 by penetrating the insulating layer disposed between the fourth conductive layer GTL4 and the fifth conductive layer SDL1. For example, the sixth conductive pattern CP6 may be electrically connected to the third conductive pattern CP3 through a seventh contact hole CH7, where the seventh contact hole CH7 is formed in the sixth insulating layer GI6 to expose a portion of the third conductive pattern CP3. Additionally, the sixth conductive pattern CP6 may be electrically connected to the second active layer ACT2 by penetrating a plurality of insulating layers disposed between the second semiconductor layer SCL2 and the fifth conductive layer SDL1. For example, the sixth conductive pattern CP6 may be electrically connected to the second source region S2 through an eighth contact hole CH8, where the eighth contact hole CH8 is formed in the fifth insulating layer GI5 and the sixth insulating layer GI6 to expose a portion of the second source region S2. In some examples, the sixth conductive pattern CP6 may be a source electrode of the second transistor T2 and may be considered as a component included in the second transistor T2.

The seventh insulating layer ILD1 may be disposed on the sixth insulating layer GI6 and the fifth conductive layer SDL1 and may cover the conductive patterns of the fifth conductive layer SDL1. For example, the seventh insulating layer ILD1 may cover the second capacitor electrode CPE2, the fifth conductive pattern CP5 and the sixth conductive pattern CP6.

The sixth conductive layer SDL2 may be disposed on the seventh insulating layer ILD1. The sixth conductive layer SDL2 may include conductive patterns including a conductive material. For example, the sixth conductive layer SDL2 may include the data line DL (or the second electrode of the second capacitor C2) connected to the pixel PX associated with FIG. 3. The data line DL may form the second capacitor C2 together with the second capacitor electrode CPE2.

The eighth insulating layer ILD2 may be disposed on the seventh insulating layer ILD1 and the sixth conductive layer SDL2 and may cover the conductive patterns of the sixth conductive layer SDL2. For example, the eighth insulating layer ILD2 may cover the data line DL.

The seventh conductive layer SDL3 may be disposed on the eighth insulating layer ILD2. The seventh conductive layer SDL3 may include conductive patterns including a conductive material. For example, the seventh conductive layer SDL3 may include the first voltage line VDL and the initialization voltage line VIL. In some embodiments, the seventh conductive layer SDL3 may further include a seventh conductive pattern CP7 of the pixel PX associated with FIG. 3.

The first voltage line VDL may be electrically connected to the second conductive pattern CP2 by penetrating a plurality of insulating layers disposed between the fourth conductive layer GTL4 and the seventh conductive layer SDL3. For example, the first voltage line VDL may be electrically connected to the second conductive pattern CP2 through a ninth contact hole CH9, where the ninth contact hole CH9 is formed in the sixth insulating layer GI6, the seventh insulating layer ILD1, and the eighth insulating layer ILD2 to expose a portion of the second conductive pattern CP2. The first voltage line VDL may be electrically connected to the first source region S1 through the second conductive pattern CP2.

The initialization voltage line VIL may be electrically connected to the fourth conductive pattern CP4 by penetrating a plurality of insulating layers disposed between the fourth conductive layer GTL4 and the seventh conductive layer SDL3. For example, the initialization voltage line VIL may be electrically connected to the fourth conductive pattern CP4 through a tenth contact hole CH10, where the tenth contact hole CH10 is formed in the sixth insulating layer GI6, the seventh insulating layer ILD1, and the eighth insulating layer ILD2 to expose a portion of the fourth conductive pattern CP4. The initialization voltage line VIL may be electrically connected to the first capacitor electrode CPE1 through the fourth conductive pattern CP4.

The seventh conductive pattern CP7 may be electrically connected to the fifth conductive pattern CP5 by penetrating the insulating layer disposed between the fifth conductive layer SDL1 and the seventh conductive layer SDL3. For example, the seventh conductive pattern CP7 may be electrically connected to the fifth conductive pattern CP5 through an eleventh contact hole CH11, where the eleventh contact hole CH11 is formed in the seventh insulating layer ILD1 and the eighth insulating layer ILD2 to expose a portion of the fifth conductive pattern CP5. The seventh conductive pattern CP7 may be electrically connected to the third drain region D3 and the first conductive pattern CP1 through the fifth conductive pattern CP5. Additionally, the seventh conductive pattern CP7 may be electrically connected to the first drain region D1 through the first conductive pattern CP1. In one embodiment, the seventh conductive pattern CP7 may be a connection pattern constituting the second node N2.

In some embodiments, the seventh conductive layer SDL3 may also include the second voltage line VSL of FIG. 2. However, the contemplated embodiments are not limited thereto, and in some embodiments, the second voltage line VSL may be disposed in another conductive layer included in the circuit layer CRL. In some examples, the second voltage line VSL may be electrically connected to a second electrode CE of the light emitting element ED inside the display area DA and/or around the display area DA.

The ninth insulating layer VIA may be disposed on the eighth insulating layer ILD2 and the seventh conductive layer SDL3 and may cover the conductive patterns of the seventh conductive layer SDL3. For example, the ninth insulating layer VIA may cover the first voltage line VDL, the initialization voltage line VIL, and the seventh conductive pattern CP7.

FIG. 3 illustrates a structure in which the light emitting element layer EDL is directly disposed on the ninth insulating layer VIA, but the embodiments contemplated by the present disclosure are not limited thereto. For example, the circuit layer CRL may also include an eighth conductive layer disposed on the ninth insulating layer VIA, where the eighth conductive layer includes an eighth conductive pattern, and a tenth insulating layer covering the conductive pattern of the eighth conductive layer. In this example, the light emitting element layer EDL may be disposed on the tenth insulating layer. The eighth conductive pattern may be electrically connected to the seventh conductive pattern CP7 through a contact hole penetrating the tenth insulating layer. Additionally, the first electrode AE of the light emitting element ED may be electrically connected to the eighth conductive pattern through a contact hole penetrating the tenth insulating layer. For example, the first electrode AE of the light emitting element ED may be electrically connected to the seventh conductive pattern CP7 through the eighth conductive pattern. In addition, the number of conductive layers and insulating layers that may be included in the circuit layer CRL may vary from that shown in FIG. 3. For instance, the circuit layer CRL may include a larger or smaller quantity of conductive layers than that shown, a larger or smaller quantity of insulating layers than that shown, and various combinations of such alternative arrangements.

The conductive patterns (e.g., conductive patterns forming each of the electrodes), the connection patterns (e.g., the first to seventh conductive patterns CP1 to CP7) and/or the wires included in each of the conductive layers of the circuit layer CRL may be single-layer or multilayer patterns including at least one conductive material. For example, each of the conductive patterns included in the first conductive layer GTL1, the second conductive layer GTL2, the third conductive layer GTL3, the fourth conductive layer GTL4, the fifth conductive layer SDL1, the sixth conductive layer SDL2, and the seventh conductive layer SDL3 may include at least one of molybdenum (Mo), aluminum (Al), chromium (Cr), gold (Au), silver (Ag), titanium (Ti), nickel (Ni), neodymium (Nd), copper (Cu), or other metals, alloys thereof, or other conductive materials, and may have a single-layer or multilayer structure. In some examples, at least two conductive layers of the conductive layers of the circuit layer CRL may include the same material. In some examples, at least two conductive layers of the conductive layers of the circuit layer CRL may include different materials. In further examples, at least two conductive layers may include the same material while another combination of at least two conductive layers may include different materials.

Each of the insulating layers of the circuit layer CRL may include at least one insulating material and may have a single-layer or multilayer structure. For example, each of the first insulating layer GI1, the second insulating layer GI2, the third insulating layer GI3, the fourth insulating layer GI4, the fifth insulating layer GI5, the sixth insulating layer GI6, the seventh insulating layer ILD1, the eighth insulating layer ILD2, and the ninth insulating layer VIA may include an organic insulating material and/or an inorganic insulating material, and may have a single-layer or multilayer structure. In some examples, at least two insulating layers of the insulating layers of the circuit layer CRL may include the same material. In some examples, at least two insulating layers of the insulating layers of the circuit layer CRL may include different materials. Thus, in some arrangements, one insulating layer may include a material absent from a second insulating layer. In further examples, at least two insulating layers may include the same material while another combination of at least two insulating layers may include different materials.

In some embodiments, each of the first insulating layer GI1, the second insulating layer GI2, the third insulating layer GI3, the fourth insulating layer GI4, the fifth insulating layer GI5, the sixth insulating layer GI6, the seventh insulating layer ILD1, and the eighth insulating layer ILD2 may be a single-layer or multilayer inorganic insulating layer including an inorganic insulating material. Examples of inorganic insulating material that may be used in the insulating layers includes, but is not limited to, silicon nitride (e.g., Si₃N₄ or SiNₓ), silicon oxide (e.g., SiO₂ or SiOₓ), silicon oxynitride (e.g., SiON), titanium oxide, aluminum oxide, or other inorganic insulating materials. Accordingly, the circuit elements disposed in the circuit layer CRL may be appropriately protected to ensure reliability, and the thickness of the circuit layer CRL may be reduced or minimized.

In some embodiments, the ninth insulating layer VIA may include an organic insulating material such as, but not limited to, acryl resin, epoxy resin, phenolic resin, polyamide resin, polyimide resin, or another organic insulating material. In some examples, the top surface of the ninth insulating layer VIA may be substantially flat. However, the contemplated embodiments are not limited thereto. For example, after the ninth insulating layer VIA is formed using an inorganic insulating material, the ninth insulating layer VIA may be planarized by a planarization process. Additionally, it should be appreciated that the material and/or structure of each of the insulating layers of the circuit layer CRL may vary from that shown in FIG. 3.

In some embodiments, the number of semiconductor layers and/or conductive layers included in the circuit layer CRL may be increased according to the design area of the circuit layer CRL. Such increase may ensure that circuit elements of the circuit layer CRL may be appropriately disposed within the circuit layer CRL, and may further ensure a satisfactory separation distance between adjacent conductive patterns. Accordingly, even in a high-resolution display device where the size of the pixel PX is small, the circuit elements of the pixel PX may be appropriately or easily disposed in each pixel area.

In some embodiments, when the number of semiconductor layers and/or conductive layers included in the circuit layer CRL increases, the depth of contact holes included in the circuit layer CRL may increase, or at least one contact hole penetrating a plurality of insulating layers may be divided into a plurality of contact holes penetrating different insulating layers. In some embodiments, the number and/or width of contact holes disposed in the circuit layer CRL may be reduced or minimized to more efficiently utilize the design area of the circuit layer CRL. To realize this efficiency, some of the contact holes disposed in each pixel area may have a relatively large depth compared to their width and area. It should be appreciated that although FIG. 3 illustrates that the contact holes have substantially the same or similar widths and the inside of each of the contact holes is completely filled with conductive patterns, the size and shape of each of the contact holes and conductive patterns may vary depending on the applicable embodiment.

A contact hole penetrating a plurality of insulating layers may have a depth corresponding to the thickness of the insulating layers through which the contact hole penetrates. For example, a contact hole that penetrates a relatively large number of insulating layers, such as the first contact hole CH1 or the second contact hole CH2, may have a relatively large depth (e.g., a depth of 1.8 μm or more). And, when the width or area of the contact hole decreases, the aspect ratio thereof may significantly increase. Accordingly, with contact holes having such characteristics, process issues such as the contact hole being incompletely formed or the inside of the contact hole being inappropriately filled with a conductive material may occur, and accordingly, may result in a contact defect.

To prevent this, according to at least some embodiments, when at least one contact hole is formed, separate portions of one or more of the insulating layers through which each contact hole passes may be sequentially etched. Accordingly, the etching depth of the insulating layers etched in a single etching process may be reduced, and each contact hole may be formed in a stable manner.

Additionally, according to at least some embodiments, when at least one contact hole is formed, wet etching (hereinafter, referred to as “BOE wet etching”) using a buffered oxide etchant (BOE) may be performed. Wet etching may be performed under conditions where a side surface of the lower insulating layer is covered with a protective film after having been etched and exposed prior to such covering. The wet etching may remove etching residues, and may clean up a surface damaged in the dry etching process (e.g., a surface of the first active layer ACT1 exposed by the first contact hole CH1, or the like). Accordingly, when the side surfaces of the insulating layers are unevenly etched within the contact hole, a stepped portion can be prevented from occurring at the sidewall of the contact hole, and a conductive pattern may be stably formed inside the contact hole. For example, according to at least some embodiments, it is possible to prevent the conductive pattern from being disconnected inside the contact hole due to a stepped portion occurring on the wall surface of the contact hole, or the like.

A detailed description of the structure and formation method of the contact hole and the conductive pattern filled in the contact hole according to at least some embodiments is provided elsewhere in the present disclosure.

The light emitting element layer EDL may be disposed on the circuit layer CRL and may be positioned in the display area DA. For example, the light emitting element layer EDL may be disposed on the circuit layer CRL in the display area DA.

The light emitting element layer EDL may include a pixel defining film PDL that partitions an emission area EA of each of the pixels PX, and the light emitting element ED disposed in the emission area EA of each of the pixels PX. In some embodiments, the light emitting element layer EDL may further include a spacer disposed on a part of the pixel defining film PDL.

The light emitting element ED may include the first electrode AE (e.g., an anode electrode), the second electrode CE (e.g., a cathode electrode) that faces the first electrode, and a light emitting layer EL disposed between the first electrode AE and the second electrode CE. In some embodiments, the first electrode AE, the light emitting layer EL, and the second electrode CE may be sequentially stacked on the circuit layer CRL along the third direction DR3.

In some embodiments, the light emitting element ED may further include at least one intermediate layer. As an example, the light emitting element ED may include a first intermediate layer (e.g., hole layer including a hole transport layer) interposed between the first electrode AE and the light emitting layer EL, and a second intermediate layer (e.g., an electron layer including an electron transport layer) interposed between the light emitting layer EL and the second electrode CE. In some embodiments, at least one intermediate layer may be a common film formed across the entire display area DA.

Although FIG. 3 discloses an embodiment in which the light emitting element ED includes the single light emitting layer EL, embodiments of the present disclosure are not limited thereto. For example, the light emitting element ED may be formed in a structure of two or more tandems including at least two light emitting layers that overlap each other in the third direction DR3 (e.g., the light emitting layer EL in FIG. 3 and an additional light emitting layer overlapping the light emitting layer EL). Additionally, the light emitting element ED may further include a charge generation layer interposed between the at least two light emitting layers. In some examples, the light emitting layer EL may be formed as a common film formed across the entire display area DA. In other examples, the light emitting layer EL may have a shape and/or size corresponding to the emission area EA of each of the pixels PX and be disposed in each pixel area.

In some embodiments, the display device 10 may further include an optical layer disposed on the light emitting element layer EDL. The optical layer may include at least one of a color filter layer (e.g., a color filter layer including color filters corresponding to the emission color of each of the pixels PX) or a light conversion layer (e.g., a light conversion layer including wavelength conversion patterns that convert the color or wavelength of light emitted from the light emitting elements ED of at least some of the pixels PX). Accordingly, the color or wavelength of light emitted from the pixels PX may be appropriately controlled. The optical layer may be optionally disposed in the display device 10 as needed. For example, depending on the type or shape of the light emitting elements ED or the structure of the light emitting element layer EDL, the display device 10 may selectively include at least one optical layer.

The first electrode AE of the light emitting element ED may be disposed on the circuit layer CRL. For example, the first electrode AE may be disposed on the ninth insulating layer VIA to correspond to a respective emission area EA.

The light emitting element ED may be electrically connected to at least one circuit element included in each of the pixels PX. For example, the light emitting element ED may be electrically connected to the first transistor T1. For example, the first electrode AE of the light emitting element ED may be electrically connected to the seventh conductive pattern CP7 through a via hole VH formed in the ninth insulating layer VIA, and may be electrically connected to the first drain region D1 of the first transistor T1 through the seventh conductive pattern CP7, the fifth conductive pattern CP5, and the first conductive pattern CP1. The first electrode AE may include at least one conductive material and may be formed as a single layer or multiple layers. In some embodiments, the first electrode AE may include a reflective electrode layer including a metal material with high reflectivity.

With continued reference to FIG. 3, an embodiment is disclosed in which the first electrode AE of the light emitting element ED is directly disposed on the circuit layer CRL, but the embodiments contemplated by the present disclosure are not limited thereto. For example, the light emitting layer EL may be formed entirely or uniformly in the display area DA, and an additional electrode or pattern may be further disposed below the first electrode AE of the light emitting element ED to adjust or optimize the resonance distance of light generated from the light emitting element ED in response to the emission wavelength of each of the pixels PX. The additional electrode or pattern may be disposed between the circuit layer CRL and the light emitting element layer EDL, or may be disposed at the inside of the circuit layer CRL, e.g., the upper layer of the circuit layer CRL, or the inside of the light emitting element layer EDL, e.g., the lower layer of the light emitting element layer EDL.

The light emitting layer EL of the light emitting element ED may include a high molecular material or a low molecular material. Light emitted from the light emitting layer EL may contribute to image display. In one embodiment, the light emitting layer EL may be provided for each pixel PX, and the light emitting layer EL of each pixel PX may emit visible light of a color or wavelength corresponding to the corresponding pixel PX. In some embodiments, the light emitting layer EL may be a common layer shared by the pixels PX of different colors, and a light conversion layer and/or color filters corresponding to the color (or wavelength) of light desired to be emitted from each pixel PX may be disposed in the emission areas EA of at least some of the pixels PX.

The second electrode CE of the light emitting element ED may include a conductive material. In one embodiment, the second electrode CE may be a common film formed across the entire display area DA to cover the light emitting layer EL and the pixel defining film PDL. In some examples, the second electrode CE may include transparent conductive oxide (TCO) such as Indium Tin Oxide or Indium Zinc Oxide capable of transmitting light. In some examples, the second electrode CE may include a semi-transmissive conductive material such as magnesium (Mg), silver (Ag), or an alloy of magnesium (Mg) and silver (Ag).

The pixel defining film PDL may have an opening corresponding to each of the emission areas EA of the display device 10 and may surround the respective emission areas EA. For example, the pixel defining film PDL may be formed to cover an edge of the first electrode AE of the light emitting element ED and may include an opening exposing the remaining portion of the first electrode AE. A region where the exposed first electrode AE and the light emitting layer EL overlap (or a region including the same) may be defined as the emission area EA of each pixel PX.

In some embodiments, the pixel defining film PDL may include an organic insulating material. For example, the pixel defining film PDL may include acrylic resin, epoxy resin, phenolic resin, polyamide resin, polyimide resin, unsaturated polyester resin, polyphenylene ether resin, polyphenylenesulfide resin, benzocyclobutene (BCB), or other organic insulating materials.

The encapsulation layer TFEL may be disposed on the light emitting element layer EDL. The encapsulation layer TFEL may cover the light emitting element layer EDL in the display area DA and may extend to the non-display area NDA to be in contact with the circuit layer CRL. For example, the encapsulation layer TFEL may be disposed in the display area DA to cover the light emitting element layer EDL, and the end of the encapsulation layer TFEL may be disposed in a portion of the non-display area NDA adjacent to the display area DA. The encapsulation layer TFEL may block the permeation of oxygen or moisture into the light emitting element layer EDL and may reduce the effect and/or occurrence of undesired electrical and/or physical impacts on the circuit layer CRL and the light emitting element layer EDL.

In some embodiments, the encapsulation layer TFEL may include multiple layers. For example, the encapsulation layer TFEL may include an inorganic encapsulation layer and an organic encapsulation layer. And, in one specific example, the encapsulation layer TFEL may include a first inorganic encapsulation layer TFE1, an organic encapsulation layer TFE2, and a second inorganic encapsulation layer TFE3 sequentially arranged on the light emitting element layer EDL. In some embodiments, the encapsulation layer TFEL may be replaced by an encapsulating member of a different type, structure and/or material. For example, the light emitting element layer EDL may be encapsulated using an upper substrate including an insulating material such as glass, or a passivation layer including a single or multilayer capping layer.

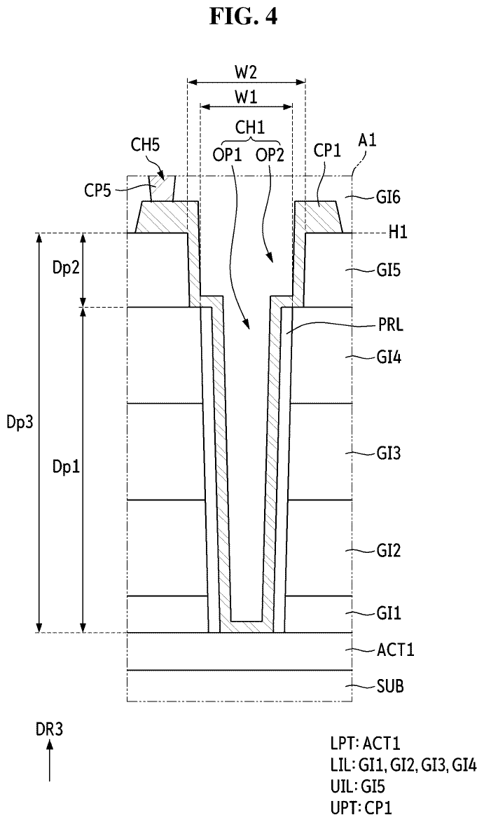

FIG. 4 is a cross-sectional view illustrating one embodiment of a contact hole, namely, a first contact hole CH1. More specifically, FIG. 4 illustrates a cross-section of one embodiment of the first contact hole CH1 within area A1 of FIG. 3 (inset A1). In this embodiment, a lower pattern and an upper pattern are connected through the contact hole, e.g., via a path of conductive material along a surface within the contact hole. For example, the first active layer ACT1 and the first conductive pattern CP1 are connected through the first contact hole CH1.

Referring to FIGS. 3 and 4, the first active layer ACT1 and the first conductive pattern CP1 may be connected through the first contact hole CH1. In FIG. 4, the first contact hole CH1 is exemplified as a contact hole that may have a structure according to one embodiment, but the contact hole to which the features and principles of the embodiment may be applied is not limited to the first contact hole CH1. For example, among the contact holes that may be disposed in the display device 10, any number of contact holes penetrating a plurality of insulating layers may have all or part of a structure or shape according to the embodiment shown in FIG. 4.

In describing example embodiments, among a pair of patterns disposed in different layers and connected to each other (e.g., electrically connected) through the respective contact holes, the pattern disposed on the lower side is referred to as “lower pattern,” and the pattern disposed on the upper side is referred to as “upper pattern.” For example, when the first active layer ACT1 and the first conductive pattern CP1 are electrically connected to each other through the first contact hole CH1 as shown in FIG. 4, the first active layer ACT1 may be a lower pattern LPT disposed below the first contact hole CH1, and the first conductive pattern CP1 may be an upper pattern UPT disposed inside and/or above the first contact hole CH1.

In some embodiments, the lower pattern LPT may be a semiconductor pattern including a semiconductor material or a conductive pattern including a conductive material. For example, the lower pattern LPT may be an active layer of a transistor, an electrode of a circuit element including a transistor, a bridge-shaped connection pattern, or a wire.

In some embodiments, the upper pattern UPT may be a conductive pattern including a conductive material. The upper pattern UPT may fill at least a portion of the contact hole. For example, the upper pattern UPT may entirely or partially fill each contact hole. The upper pattern UPT may be connected to the lower pattern LPT through each contact hole. For example, the upper pattern UPT may be in contact with (e.g., directly in contact with) the lower pattern LPT at the bottom surface of each contact hole.

In some embodiments, at least one contact hole may penetrate a plurality insulating layers. The above-described plurality of insulating layers may include a lower insulating layer LIL and an upper insulating layer UIL disposed between the lower pattern LPT and the upper pattern UPT connected through the contact hole. The lower insulating layer LIL and the upper insulating layer UIL may be sequentially disposed or stacked on the lower pattern LPT. Each of the lower insulating layer LIL and the upper insulating layer UIL may include at least one insulating layer. Each contact hole may expose a portion of the lower pattern LPT by penetrating the lower insulating layer LIL and the upper insulating layer UIL. For example, each contact hole may include a first opening OP1 formed in the lower insulating layer LIL and a second opening OP2 formed in the upper insulating layer UIL, the second opening OP2 being in communication with the first opening OP1.

In one example, a pair of layers including lower insulating layer LIL and upper insulating layer UIL may be sequentially disposed or stacked on the first active layer ACT1. The first contact hole CH1 may expose a portion of the first active layer ACT1 by penetrating the lower insulating layer LIL and the upper insulating layer UIL. The first contact hole CH1 may include the first opening OP1 formed in the lower insulating layer LIL and the second opening OP2 formed in the upper insulating layer UIL. The first opening OP1 and the second opening OP2 may be formed to communicate with each other and may expose a portion of the first active layer ACT1. The first opening OP1 may include a lower layer of the first contact hole CH1, and the second opening OP2 may include an upper layer of the first contact hole CH1.

In some embodiments, the first contact hole CH1 may penetrate three or more insulating layers, and the lower insulating layer LIL may include a plurality of insulating layers sequentially stacked on the lower pattern LPT. For example, the lower insulating layer LIL may include the first insulating layer GI1, the second insulating layer GI2, the third insulating layer GI3, and the fourth insulating layer GI4, and the upper insulating layer UIL may include the fifth insulating layer GI5. The first opening OP1 may be an opening formed in the first insulating layer GI1, the second insulating layer GI2, the third insulating layer GI3, and the fourth insulating layer GI4 to expose the first active layer ACT1 in an area corresponding to a location of the first contact hole CH1. The second opening OP2 may be an opening formed in the fifth insulating layer GI5 to expose the first active layer ACT1 via communication of the second opening OP1 with the first opening OP1.

The first opening OP1 may have a first depth Dp1 corresponding to the thickness of the lower insulating layer LIL, and the second opening OP2 may have a second depth Dp2 corresponding to the thickness of the upper insulating layer UIL. For example, the first depth Dp1 may correspond to the sum of the thicknesses of the first insulating layer GI1, the second insulating layer GI2, the third insulating layer GI3, and the fourth insulating layer GI4, and the second depth Dp2 may correspond to the thickness of the fifth insulating layer GI5. The first contact hole CH1 may have a third depth Dp3 corresponding to the sum of the first depth Dp1 and the second depth Dp2.

In forming the display device 10 according to some embodiments, the first opening OP1 and the second opening OP2 may be sequentially formed by sequentially etching the lower insulating layer LIL and the upper insulating layer UIL. For example, after forming the lower insulating layer LIL on the first active layer ACT1, the lower insulating layer LIL may be etched to form the first opening OP1. Thereafter, the upper insulating layer UIL (or an insulating film for forming the upper insulating layer UIL) may be formed on the lower insulating layer LIL in which the first opening OP1 is formed. The upper insulating layer UIL may be etched to form the second opening OP2.

As the first opening OP1 and the second opening OP2 are sequentially formed by performing at least two etching processes, the etching depths of the insulating layers etched in each etching process may be reduced relative to what would be required if a single etching process were used. For example, when the first contact hole CH1 having the third depth Dp3 is formed by etching the lower insulating layer LIL and the upper insulating layer UIL at once through a single etching process, it may become difficult to stably form the first contact hole CH1, particularly when the third depth Dp3 increases. For example, when the first contact hole CH1 is formed having the third depth Dp3 greater than or equal to a reference depth (e.g., a depth at which the insulating layers may be stably etched by one etching process), the first contact hole CH1 may not be stably formed up to the third depth Dp3 when the lower insulating layer LIL and the upper insulating layer UIL are etched at once in a single etching process to form the first contact hole CH1. For example, when the third depth Dp3 is 1.8 μm or more, the first insulating layer GI1 may not be etched to the entire thickness thereof on the bottom surface of the first contact hole CH1 and may cover the first active layer ACT1. Accordingly, the first active layer ACT1 and the first conductive pattern CP1 may not be appropriately or stably connected inside the first contact hole CH1, and a contact defect may occur. On the other hand, when the lower insulating layer LIL and the upper insulating layer UIL are etched sequentially according to an embodiment, the depth at which the insulating layers are etched by a single etching process may be reduced. For example, each of the first depth Dp1 and the second depth Dp2 may be less than 1.8 μm. Accordingly, the insulating layers may be stably etched to appropriately expose the first active layer ACT1 in the first contact hole CH1, and the contact quality between the first active layer ACT1 and the first conductive pattern CP1 may be improved.

In some embodiments, the lower insulating layer LIL may include a plurality of insulating layers including different materials. For example, one of the plurality of insulating layers forming the lower insulating layer LIL may include silicon oxide, and another of the insulating layers may include silicon nitride. The insulating layers of the circuit layer CRL may be formed of materials and/or thicknesses optimized to ensure or improve the characteristics of the circuit elements disposed in the circuit layer CRL and to appropriately block moisture permeation or the like.

In some embodiments, the display device 10 may further include a protective film PRL disposed inside the contact hole penetrating the lower insulating layer LIL and the upper insulating layer UIL and covering a side surface of the lower insulating layer LIL. For example, in the first contact hole CH1 of FIG. 4, the protective film PRL may be disposed inside the first contact hole CH1 to cover the side surfaces of the first, second, third, and fourth insulating layers GI1, GI2, GI3, and GI4 exposed by the first opening OP1.

The protective film PRL may entirely cover the side surface of the lower insulating layer LIL at the sidewall portion of the contact hole, and may expose the lower pattern LPT at the bottom portion of the contact hole. For example, the protective film PRL disposed inside the first contact hole CH1 may entirely cover the side surfaces of the first, second, third, and fourth insulating layers GI1, GI2, GI3, and GI4 at the sidewall portion of the first contact hole CH1, and may expose the first active layer ACT1 at the bottom portion of the first contact hole CH1.

The protective film PRL may be formed to cover the side surface of the lower insulating layer LIL before etching the upper insulating layer UIL. Accordingly, it is possible to prevent an undercut from occurring due to uneven etching of the side surface of the lower insulating layer LIL during the etching process of the upper insulating layer UIL to form the second opening OP2 or a during post-treatment process such as BOE wet etching performed after the formation of the second opening OP2.

For example, when the lower insulating layer LIL exposed by the first opening OP1 includes a plurality of insulating layers including different materials, the etch selectivities of the plurality of insulating layers with respect to the BOE may be different. For example, at least one insulating layer of the lower insulating layers LIL may include silicon oxide, and at least one other insulating layer of the lower insulating layers LIL may include silicon nitride. Accordingly, when BOE wet etching is performed in the first contact hole CH1 under conditions where the side surface of the lower insulating layer LIL is exposed by the first opening OP1, the sidewall of the first contact hole CH1 may have a stepped portion having an undercut form. On the other hand, when BOE wet etching is performed under conditions where the sidewall of the first contact hole CH1 is covered with the protective film PRL, as would be the case with CH1 of FIG. 4, for example, the side surface of the lower insulating layer LIL may not be substantially etched, and since the etch selectivity of the protective film PRL with respect to the BOE is uniform, the sidewall of the first contact hole CH1 may be covered with the protective film PRL having a smooth form. Accordingly, the first conductive pattern CP1 may be stably formed inside the first contact hole CH1, and disconnected sections along the first conductive pattern CP1 or other breaks in the first conductive pattern CP1 may be prevented.

In some embodiments, the protective film PRL and the upper insulating layer UIL may be formed simultaneously using the same material. Accordingly, the protective film PRL and the upper insulating layer UIL may contain the same material. By forming the protective film PRL and the upper insulating layer UIL simultaneously, the side surface of the lower insulating layer LIL exposed by the first contact hole CH1 may be appropriately covered without adding a separate process for forming the protective film PRL. Accordingly, the manufacturing process of the display device 10 may be streamlined while also preventing contact defects along the applicable contact hole.

In some embodiments, an insulating material may be applied on the lower insulating layer LIL, in which the first opening OP1 is formed, to form an insulating film, and the insulating film may be etched to form the protective film PRL and the upper insulating layer UIL. When the insulating film is formed, an insulating film having a relatively small thickness may be formed inside the first opening OP1 compared to the upper side of the lower insulating layer LIL. Accordingly, the thickness of the protective film PRL may be smaller than the thickness of the upper insulating layer UIL. When the small-thickness insulating film is formed inside the first opening OP1, the insulating film disposed on the bottom surface of the first opening OP1 may be smoothly removed during the etching process of the insulating film, and the first active layer ACT1 may be exposed in a stable manner.

In some embodiments, the first opening OP1 and the second opening OP2 may be formed with different widths, and the protective film PRL and the upper insulating layer UIL may be separated or spaced apart from each other. For example, in the first contact hole CH1 in FIG. 4, the first opening OP1 may have a first width W1, and the second opening OP2 may have a second width W2 greater than the first width W1. When viewed in plan view, the first opening OP1 may be entirely within the second opening OP2, and an edge portion of the first opening OP1 may not meet an edge portion of the second opening OP2. Accordingly, a stepped portion may occur on the sidewall of the first contact hole CH1. For example, the first contact hole CH1 may have a step-shaped portion at the boundary portion between the first opening OP1 and the second opening OP2. Additionally, the first contact hole CH1 may have a shape in which the width thereof is expanded at the entrance portion thereof.

As the width of the first contact hole CH1 is expanded at the entrance portion of the first contact hole CH1, the first conductive pattern CP1 may be formed more stably on the first contact hole CH1. For example, in a film forming process of a conductive film to form the first conductive pattern CP1, a conductive material may be excessively deposited at the entrance portion of the first contact hole CH1 to cause the conductive material to protrude over the contact hole and create an overhang. However, with an expanded opening at an entrance of the first contact hole CH1, e.g., second opening OP2, the conductive material may be prevented from blocking the entrance of the first contact hole CH1. Accordingly, the conductive material may be appropriately deposited inside the first contact hole CH1. Further, in some examples, the conductive material may also be deposited on the sidewall and bottom surface of the first contact hole CH1 to a thickness sufficient to ensure contact quality. Accordingly, disconnections along the first conductive pattern CP1 may be prevented, and the quality of contact by the first conductive pattern CP1 may be improved.

The first conductive pattern CP1 may be disposed on the upper insulating layer UIL and the protective film PRL. Additionally, in some embodiments, the first conductive pattern CP1 may cover a portion of the first active layer ACT1 exposed by the first contact hole CH1.

For example, and with reference to FIG. 4, a portion of the first conductive pattern CP1 positioned at a height lower than or equal to a first height H1, where first height H1 corresponds to the maximum height of the first contact hole CH1, may be disposed inside the first contact hole CH1, and another portion of the first conductive pattern CP1 may be disposed around the first contact hole CH1. The first conductive pattern CP1 may cover the first contact hole CH1 in plan view (e.g., when viewed on a plane coincident with the first direction DR1 and the second direction DR2) and may also be disposed at the perimeter of the first contact hole CH1. Inside the first contact hole CH1, the first conductive pattern CP1 may cover a portion of the first active layer ACT1 exposed by the first contact hole CH1, the protective film PRL, and a side surface of the upper insulating layer UIL. Around the first contact hole CH1, the first conductive pattern CP1 may cover the upper insulating layer UIL.

Meanwhile, as to the pixel area (e.g., a representative pixel area) of the display device 10, depicted schematically in FIG. 3, while each contact hole is illustrated as being completely filled with each of the upper patterns UPT, the embodiments are not limited thereto. For example, each of the upper patterns UPT may entirely or partially fill each contact hole. For example, as illustrated in FIG. 4, the first conductive pattern CP1 may partially fill the inside of the first contact hole CH1 and may cover the bottom surface and side surface of the first contact hole CH1. The first conductive pattern CP1 may be formed continuously from the upper portion of the first contact hole CH1 to the bottom surface of the first contact hole CH1, and may be in contact with the first active layer ACT1 at the bottom surface of the first contact hole CH1.

The first conductive pattern CP1 may have a shape corresponding to the shape of the first contact hole CH1. For example, the first conductive pattern CP1 may have a step-shaped cross-section on the boundary portion between the lower insulating layer LIL and the upper insulating layer UIL. In some embodiments, the boundary portion of the lower insulating layer LIL and the upper insulating layer UIL may be adjacent to the entrance portion of the first contact hole CH1, and accordingly, when forming a conductive film for forming the first conductive pattern CP1, a conductive material may be deposited to have a sufficient thickness (e.g., a thickness sufficient to prevent disconnection of the first conductive pattern CP1 and to ensure contact quality) even inside the first contact hole CH1. Accordingly, although the first conductive pattern CP1 has a stepped portion on the boundary portion between the lower insulating layer LIL and the upper insulating layer UIL, the first conductive pattern CP1 may be formed in a stable manner.

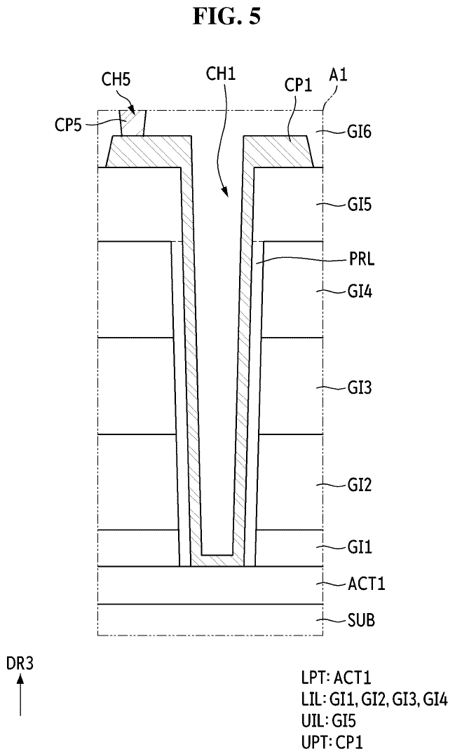

FIG. 5 is a cross-sectional view illustrating a contact hole, and a lower pattern and an upper pattern connected through the contact hole according to one embodiment. Specifically, FIG. 5 is a cross-section of one embodiment of the first contact hole CH1 within area A1 of FIG. 3, along with the first active layer ACT1 and the first conductive pattern CP1 connected through the first contact hole CH1.

FIG. 5 illustrates an embodiment that is different from FIG. 4 in terms of the shape of the first contact hole CH1, and the relative positions of the upper insulating layer UIL and the protective film PRL, i.e., the absence of separation between the upper insulating layer UIL and the protective film PRL. In describing the embodiment depicted in FIG. 5, components substantially identical or similar to those of at least one embodiment described above are designated with the same reference numerals, and redundant descriptions will be omitted.

Referring to FIG. 5, the upper insulating layer UIL and the protective film PRL may be connected continuously. For example, the upper insulating layer UIL and the protective film PRL may be integral and may substantially form one insulating layer, i.e., a singular insulating layer. In some examples, the one insulating layer may be smoothly connected without a stepped portion at the boundary between the upper insulating layer UIL and the protective film PRL. Accordingly, the first conductive pattern CP1 may have a smoother shape on the sidewall of the first contact hole CH1. In some examples, the first conductive pattern CP1 may have a cross-sectional shape that is smoothly connected even on the boundary portion between the lower insulating layer LIL and the upper insulating layer UIL.

In FIG. 5, the first opening OP1 and the second opening OP2 of the first contact hole CH1 are not distinguishable in the sense that there is no step between the respective openings, but in the same manner as in FIG. 4, the first opening OP1 is formed in the lower insulating layer LIL and the second opening OP2 is formed in the upper insulating layer UIL. Even in a case of forming the display device 10 according to the embodiment of FIG. 5, after the first opening OP1 is formed by etching the lower insulating layer LIL, the upper insulating layer UIL and the protective film PRL may be formed. For example, after the lower insulating layer LIL is etched, the protective film PRL covering a side surface of the lower insulating layer LIL and the upper insulating layer UIL including the second opening OP2 may be formed. Accordingly, the first contact hole CH1 may be stably formed in the lower insulating layer LIL and in the upper insulating layer UIL. Further, the first active layer ACT1 and the first conductive pattern CP1 may be stably connected by the first contact hole CH1.

Additionally, even in a case of forming the display device 10 according to the embodiment of FIG. 5, the side surface of the lower insulating layer LIL may be protected by the protective film PRL. Accordingly, uneven etching of the lower insulating layer LIL by the BOE or the like may be prevented. As a result, an undercut may be prevented from occurring at the sidewall of the first contact hole CH1, and the first conductive pattern CP1 may be stably formed inside the first contact hole CH1.

The embodiment of FIG. 4 or FIG. 5 may be applied to a contact hole having a relatively large depth, e.g., relative to other contact holes, such as the first contact hole CH1, but is not limited thereto. For example, any one or more contact holes of the contact holes of the circuit layer CRL may have a structure or shape according to at least one embodiment of the embodiments contemplated by the present disclosure.

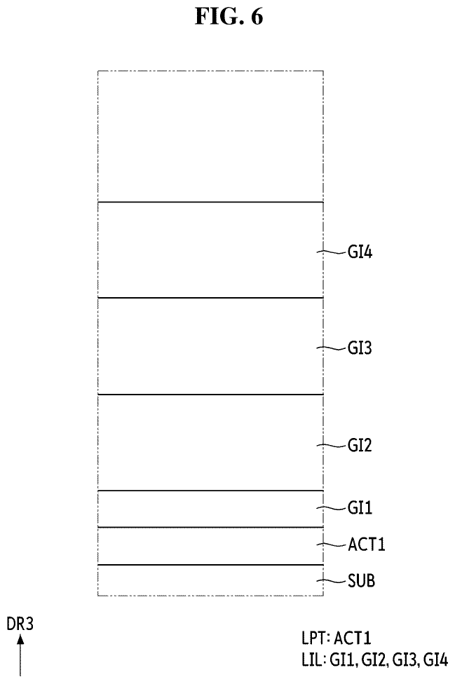

FIGS. 6 to 13 are cross-sectional views showing a method of manufacturing the display device according to one embodiment. For example, among manufacturing steps for manufacturing the components of display device 10 shown in FIGS. 1-3, FIGS. 6 to 13 sequentially illustrate the manufacturing steps for forming the first contact hole CH1, the protective film PRL covering the first contact hole CH1, the upper insulating layer UIL, and the first conductive pattern CP1 according to the embodiment of FIG. 4. FIGS. 6 to 13 illustrate a portion of the display device 10 being manufactured corresponding to FIG. 4, in turn representing inset A1 of FIG. 3.

Referring to FIG. 6, first, the lower pattern LPT and the lower insulating layer LIL covering the lower pattern LPT may be formed on the substrate SUB (or a buffer layer on the substrate SUB). For example, the first semiconductor layer SCL1 including the first active layer ACT1 (see FIG. 3) may be formed on the substrate SUB (or buffer layer), and the first insulating layer GI1, the second insulating layer GI2, the third insulating layer GI3, and the fourth insulating layer GI4 may be sequentially formed on the first semiconductor layer SCL1.

The first semiconductor layer SCL1 may be formed by a semiconductor film forming process (e.g., a deposition process) using at least one semiconductor material (e.g., the semiconductor material previously exemplified as the material of the first active layer ACT1) and a patterning process (e.g., an etching process using a mask, or the like) on the semiconductor film. Each of the first insulating layer GI1, the second insulating layer GI2, the third insulating layer GI3, and the fourth insulating layer GI4 may be formed by a film forming process (e.g., a deposition process) of at least one layer of an insulating film using at least one insulating material (e.g., silicon oxide, silicon nitride, silicon oxynitride, and/or other inorganic insulating materials).

In some embodiments, and with reference to FIG. 3, when the first conductive layer GTL1, the second conductive layer GTL2, and the third conductive layer GTL3 are disposed between the first insulating layer GI1 and the fourth insulating layer GI4, the first insulating layer GI1 may be formed on the first semiconductor layer SCL1, and then the first conductive layer GTL1, the second insulating layer GI2, the second conductive layer GTL2, the third insulating layer GI3, the third conductive layer GTL3, and the fourth insulating layer GI4 may be sequentially formed on the first insulating layer GI1. Each of the first conductive layer GTL1, the second conductive layer GTL2, and the third conductive layer GTL3 may be formed by a film forming process (e.g., a deposition process) of a conductive film using at least one conductive material (e.g., a conductive material such as those described above) and a patterning process (e.g., an etching process using a mask, or the like) on the conductive film.

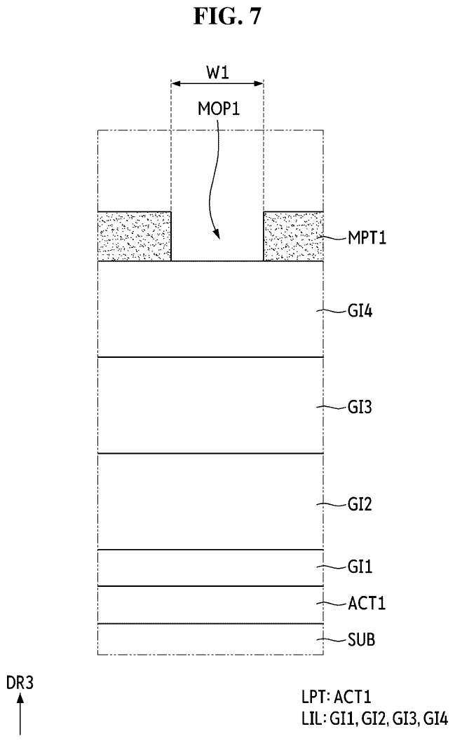

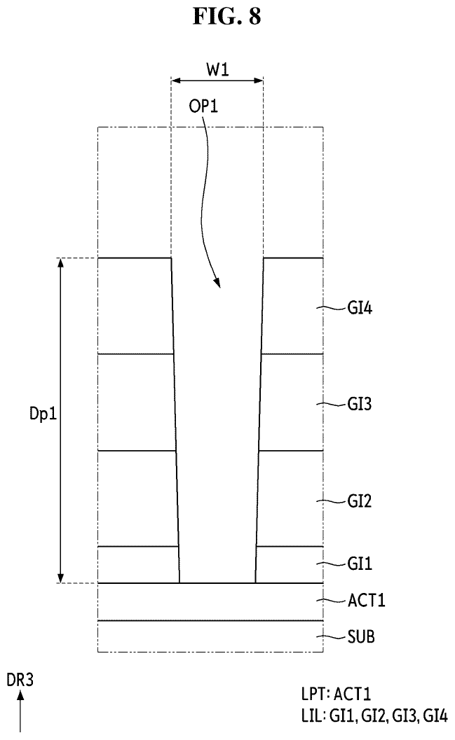

Referring to FIGS. 7 and 8, the first opening OP1 exposing a portion of the lower pattern LPT may be formed by etching the lower insulating layer LIL. For example, as illustrated in FIG. 7, a first mask pattern MPT1 may be disposed on the lower insulating layer LIL, and as illustrated in FIG. 8, a portion of the lower insulating layer LIL that is not covered by the first mask pattern MPT1 may be etched. As a result, the first opening OP1 exposing a portion of the first active layer ACT1 may be formed in the lower insulating layer LIL.

The first mask pattern MPT1 may include an opening MOP1 exposing a portion of the lower insulating layer LIL corresponding to an area in which the first opening OP1 is to be formed, and may cover another portion of the lower insulating layer LIL. In some examples, the first mask pattern MPT1 may be a photoresist pattern formed by a mask process including a photoresist process.

In one embodiment, the first mask pattern MPT1 may include the opening MOP1 having a width corresponding to the first width W1. Accordingly, the first opening OP1 having the first width W1 may be formed. The first mask pattern MPT1 may be removed after the first opening OP1 is formed.

In some embodiments, the lower insulating layer LIL may be etched by a dry etching process. For example, the first opening OP1 may be formed in the lower insulating layer LIL by etching a portion of the lower insulating layer LIL exposed by the opening MOP1 of the first mask pattern MPT1 in a perpendicular direction (e.g., a direction substantially perpendicular to the lower insulating layer LIL, including the thickness direction of the lower insulating layer LIL, third direction DR3) using a dry etching method. In some examples, the sidewall of the first opening OP1 may have a slight slope depending on process conditions under which the dry etching process is performed.

The first opening OP1 may be formed to penetrate the first insulating layer GI1, the second insulating layer GI2, the third insulating layer GI3, and the fourth insulating layer GI4 to expose a portion of the first active layer ACT1. For example, the lower insulating layer LIL may be etched until the first active layer ACT1 is appropriately exposed through the first opening OP1.

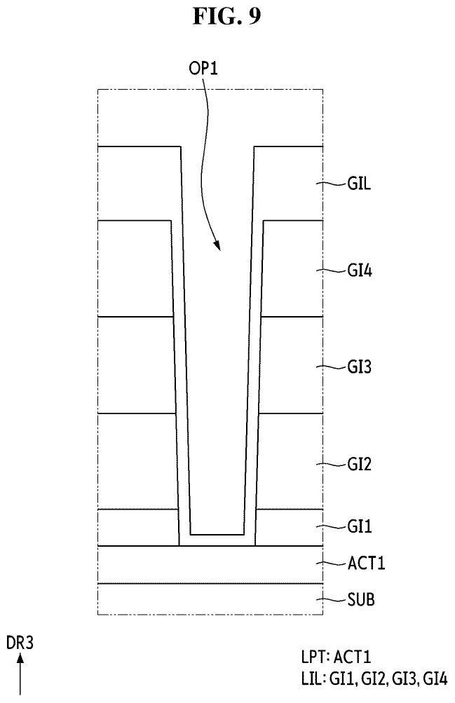

Referring to FIG. 9, an insulating film GIL may be formed on the lower pattern LPT and the lower insulating layer LIL. The insulating film GIL may be formed as a single layer or multiple layers by using at least one insulating material (e.g., silicon oxide, silicon nitride, silicon oxynitride, and/or other inorganic insulating materials). For example, the insulating film GIL may be formed by applying (e.g., depositing) at least one insulating material entirely on the lower insulating layer LIL in which the first opening OP1 is formed, the single-layer or multilayer insulating film GIL entirely covering the lower pattern LPT and the lower insulating layer LIL. In some examples, the insulating film GIL may be formed of a single silicon oxide film or silicon nitride film. In other examples, the insulating film GIL may be formed of a multifilm including a silicon oxide film and a silicon nitride film or a multifilm including a silicon oxide film and a silicon oxynitride film, or the like. The material or structure of the insulating film GIL may vary depending on the properties required for the upper insulating layer UIL and the protective film PRL to be formed from the insulating film GIL.

The insulating film GIL may cover a portion of the lower pattern LPT and a side surface of the lower insulating layer LIL that is exposed by the first opening OP1. The insulating film GIL may be formed with a relatively small thickness inside the first opening OP1 compared to other portions, such as the insulating layers.

The insulating film GIL may be used to form the upper insulating layer UIL and the protective film PRL. For example, the insulating film GIL may be etched in a subsequent process to form the upper insulating layer UIL and the protective film PRL.

In some embodiments, the second semiconductor layer SCL2 may be disposed between the lower insulating layer LIL and the upper insulating layer UIL, for example, between the fourth insulating layer GI4 and the fifth insulating layer GI5, as illustrated in FIG. 3. In some examples of these embodiments, the second semiconductor layer SCL2 may be first formed on the fourth insulating layer GI4, and the insulating film GIL may be formed on the second semiconductor layer SCL2. The second semiconductor layer SCL2 may be formed by a semiconductor film forming process using at least one semiconductor material (e.g., the semiconductor material previously exemplified as the material of the second active layer ACT2) and a patterning process on the semiconductor film.

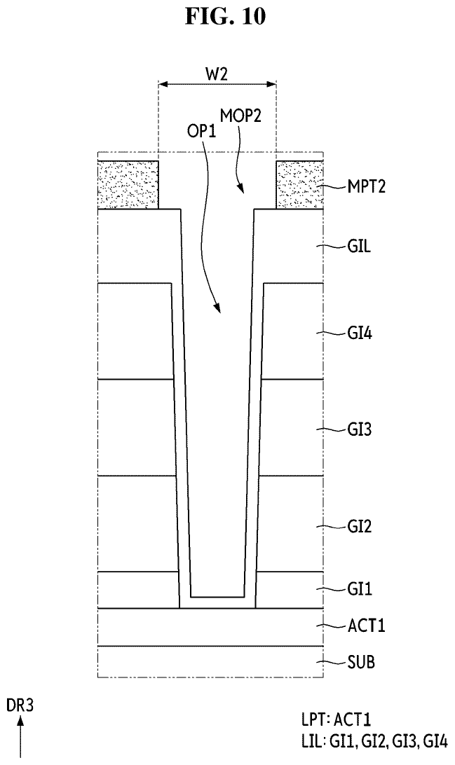

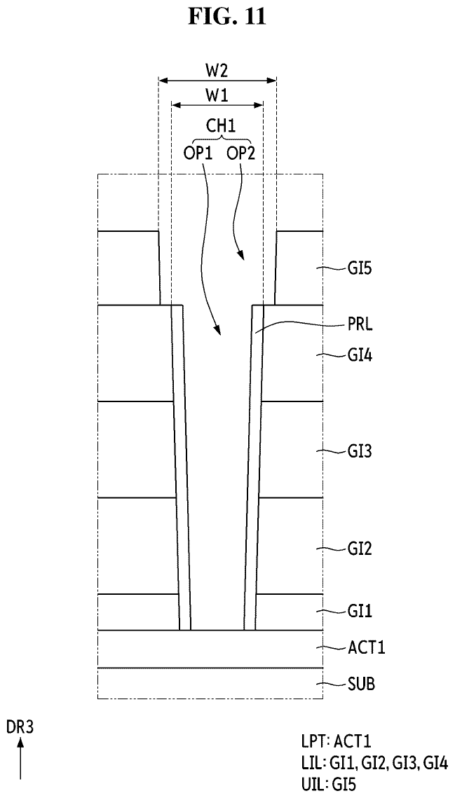

Referring to FIGS. 10 and 11, the protective film PRL and the upper insulating layer UIL may be formed by etching the insulating film GIL. For example, as illustrated in FIG. 10, a second mask pattern MPT2 may be disposed on the insulating film GIL, and as illustrated in FIG. 11, a portion of the insulating film GIL not covered by the second mask pattern MPT2 may be etched to form the protective film PRL and the upper insulating layer UIL. The protective film PRL may be formed to cover the side surface of the lower insulating layer LIL exposed through the first opening OP1. The upper insulating layer UIL may be formed to define the second opening OP2 over the lower insulating layer LIL and in communication with the first opening OP1.

The second mask pattern MPT2 may include an opening MOP2 exposing a portion of the insulating film GIL corresponding to an area in which the second opening OP2 is to be formed, and may cover other portions of the insulating film GIL. In one embodiment, the second mask pattern MPT2 may be a photoresist pattern formed by a mask process including a photoresist process.

The opening MOP2 of the second mask pattern MPT2 may expose the first opening OP1. In one embodiment, the second mask pattern MPT2 may include the opening MOP2 having a width corresponding to the second width W2, where the second width W2 is greater than the width (e.g., the first width W1) of the first opening OP1. Accordingly, the second opening OP2 having the second width W2 may be formed.

However, the methods of manufacturing a display device as contemplated by the present disclosure are not limited thereto. For example, the second width W2 of the second mask pattern MPT2 may be substantially equal to the first width W1 of the first opening OP1. In this case, the first opening OP1 and the second opening OP2 may have a continuously connected form (e.g., openings formed in the process of forming the first contact hole CH1 depicted in FIG. 5).

With continued reference to FIG. 11, the second opening OP2 may be formed to communicate with the first opening OP1, and the first opening OP1 and the second opening OP2 may form the first contact hole CH1. The second mask pattern MPT2 may be removed after the first contact hole CH1 is formed.

In some embodiments, the insulating film GIL may be etched in one direction by an anisotropic etching process. For example, in a state where the second mask pattern MPT2 is disposed on the insulating film GIL, the insulating film GIL may be etched in a perpendicular direction, e.g., in the third direction DR3, by a dry etching method. Accordingly, etching or consumption of the insulating film GIL on the side surface of the lower insulating layer LIL may be minimized. The insulating film GIL may be etched until the first active layer ACT1 is appropriately exposed by the first contact hole CH1 where the first contact hole CH1 encompasses the first opening OP1 and the second opening OP2.

In some embodiments, the etching conditions of the insulating film GIL may be controlled such that the insulating film GIL remains on the side surface of the lower insulating layer LIL. For example, in a dry etching process for forming the second opening OP2, the insulating film GIL may be etched such that the insulating film GIL having a reference thickness or greater remains on the side surface of the lower insulating layer LIL exposed by the first opening OP1. The reference thickness may be set to a thickness that allows the lower insulating layer LIL to be appropriately protected by the protective film PRL in a post-treatment process including BOE wet etching or the like.

A portion of the insulating film GIL that remains on the side surface of the lower insulating layer LIL after the etching process (etching the insulating film GIL) may be the protective film PRL. Another portion of the insulating film GIL disposed over the lower insulating layer LIL and covered with the second mask pattern MPT2 may be the upper insulating layer UIL.

In some embodiments, the second mask pattern MPT2 may expose the first opening OP1 and the insulating film GIL around the first opening OP1. For example, the opening MOP2 of the second mask pattern MPT2 may expose the first opening OP1 and a portion of the insulating film GIL positioned around the first opening OP1, and the second mask pattern MPT2 may be disposed on separate portion of the insulating film GIL peripheral to the exposed portion. For example, when viewed in plan view, the opening MOP2 of the second mask pattern MPT2 may have a larger size than the first opening OP1 and may be positioned outside the first opening OP1 and spaced apart from the first opening OP1. Accordingly, the protective film PRL and the upper insulating layer UIL may be formed to be separated or spaced from each other, and the first contact hole CH1 may have an expanded size at the entrance portion thereof relative to a portion defined within the lower insulating layer LIL.

In some embodiments, a post-treatment process including BOE wet etching may be performed after the dry etching process that is used to form the second opening OP2 is completed. Accordingly, the etching residue may be appropriately removed, and the surface of the first active layer ACT1 or the like exposed through the first contact hole CH1 may be more uniformly finished and exposed. BOE wet etching may be performed while the side surface of the lower insulating layer LIL is covered with the protective film PRL. Accordingly, it is possible to prevent the side surface of the lower insulating layer LIL in the first contact hole CH1 from being etched unevenly.

In some embodiments, in the process of forming the first contact hole CH1, other contact holes penetrating at least some of the insulating layers through which the first contact hole CH1 passes may be formed simultaneously with the first contact hole CH1. For example, in the step of forming the first contact hole CH1, one or more of the second contact hole CH2, the third contact hole CH3, and the fourth contact hole CH4, each as shown in FIG. 3, may be formed simultaneously.

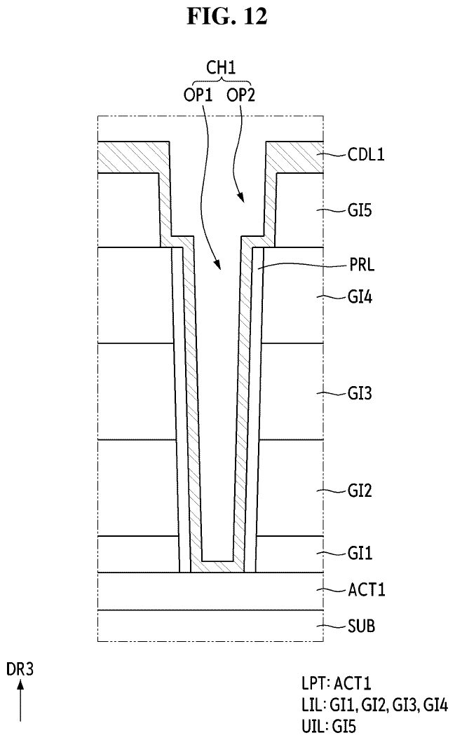

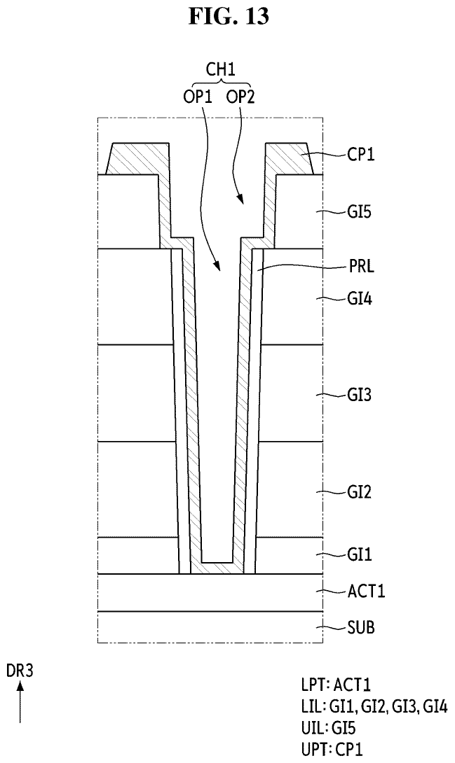

Referring to FIGS. 12 and 13, the upper pattern UPT may be formed to cover a depth of the first contact hole CH1. For example, the upper pattern UPT may be formed on each of a portion of the lower pattern LPT exposed by the first contact hole CH1, the protective film PRL, and the upper insulating layer UIL. The upper pattern UPT may be connected to the lower pattern LPT through the first contact hole CH1. For example, as illustrated in FIG. 12, a conductive film CDL1 may be formed on the lower pattern LPT, the protective film PRL, and the upper insulating layer UIL. And, as illustrated in FIG. 13, the conductive film CDL1 may be etched to form the first conductive pattern CP1. The first conductive pattern CP1 may be connected to the first active layer ACT1 through the first contact hole CH1.

The conductive film CDL1 may be formed as a single layer or multiple layers by using at least one conductive material (e.g., the conductive material exemplified above). For example, by applying (e.g., depositing) at least one conductive material entirely on the upper insulating layer UIL in which the first contact hole CH1 is formed, the single-layer or multilayer conductive film CDL1 that entirely covers the first contact hole CH1, the protective film PRL, and the upper insulating layer UIL may be formed.

The upper pattern UPT may be formed by performing a patterning process (e.g., an etching process using a mask, or the like) on the conductive film CDL1. For example, the first conductive pattern CP1 may be formed by etching the conductive film CDL1 with the use of a mask.

In some embodiments, patterns disposed in the same conductive layer as the first conductive pattern CP1 may be formed simultaneously. For example, by performing the film forming process and patterning process on the conductive film CDL1, the patterns of the first conductive pattern CP1 and the other conductive components of the fourth conductive layer GTL4 may be formed simultaneously.

By the process described above with reference to FIGS. 6 to 13, the first semiconductor layer SCL1, the first insulating layer GI1, the first conductive layer GTL1, the second insulating layer GI2, the second conductive layer GTL2, the third insulating layer GI3, the third conductive layer GTL3, the fourth insulating layer GI4, the second semiconductor layer SCL2, the fifth insulating layer GI5, and the fourth conductive layer GTL4 may be formed on the substrate SUB.

Thereafter, a remainder of the circuit layer CRL may be formed by forming the sixth insulating layer GI6, the fifth conductive layer SDL1, the seventh insulating layer ILD1, the sixth conductive layer SDL2, the eighth insulating layer ILD2, the seventh conductive layer SDL3, and the ninth insulating layer VIA, all on the fourth conductive layer GTL4, as shown in FIG. 3, for example. The circuit layer CRL may include the via hole VH exposing a portion of the seventh conductive pattern CP7 in each pixel area.

Thereafter, the light emitting element layer EDL and the encapsulation layer TFEL, such as those shown in FIG. 3, may be sequentially formed on the circuit layer CRL. Thus, the display device 10 according to the embodiment of FIG. 3 may be manufactured.

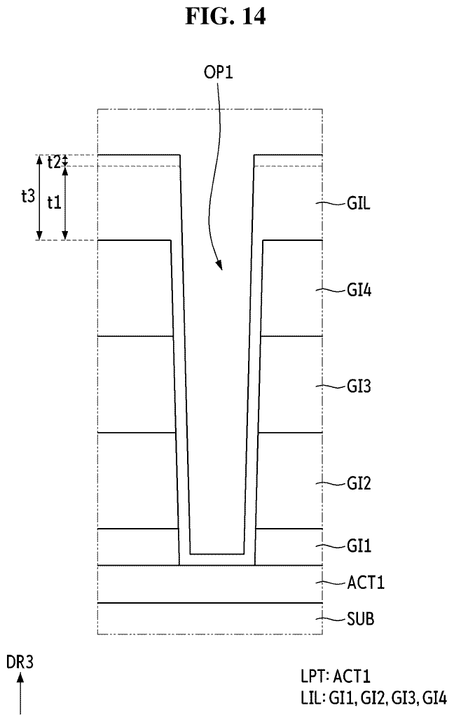

FIGS. 14 to 17 are cross-sectional views showing a method of manufacturing the display device according to one embodiment. For example, among manufacturing steps for manufacturing components of the display device 10 shown in FIGS. 1 to 3, FIGS. 14 to 17 sequentially illustrate manufacturing steps for forming the first contact hole CH1, the protective film PRL covering the first contact hole CH1, the upper insulating layer UIL, and the first conductive pattern CP1 according to the embodiment of FIG. 5. FIGS. 14 to 17 illustrate a portion of the display device 10 being manufactured, corresponding to FIG. 5, in turn representing inset A1 of FIG. 3.

Prior to arriving at a step illustrated in FIG. 14, and with initial reference to FIGS. 6 to 8, the lower pattern LPT and the lower insulating layer LIL covering the lower pattern LPT may be formed on the substrate SUB (or buffer layer), and the first opening OP1 may be formed by etching the lower insulating layer LIL. Thereafter, as illustrated in FIG. 14, the insulating film GIL may be formed on the lower pattern LPT and the lower insulating layer LIL. For example, by applying at least one insulating material entirely on the lower insulating layer LIL in which the first opening OP1 is formed, the single-layer or multilayer insulating film GIL that entirely covers the lower pattern LPT and the lower insulating layer LIL may be formed.

In some embodiments, the insulating film GIL may be formed to have a thickness equal to or greater than a target thickness of the upper insulating layer UIL to be formed in a subsequent process. For example, when it is desired to form the upper insulating layer UIL having a first thickness t1, the insulating film GIL may be formed such that the insulating film GIL has a third thickness t3 corresponding to the sum of the first thickness t1 and a second thickness t2 on the lower insulating layer LIL. The second thickness t2 may correspond to the thickness at which the insulating film GIL is etched in a subsequent process, and may be set considering an error range. Such an approach may also be utilized to form the first contact hole CH1 as described in FIGS. 6-13 or in other embodiments contemplated by the present disclosure.

The insulating film GIL may be formed with a relatively small thickness inside the first opening OP1. In one embodiment, the insulating film GIL on the bottom surface of the first opening OP1 may be formed to have a thickness substantially equal to or similar to the second thickness t2, but is not limited thereto.

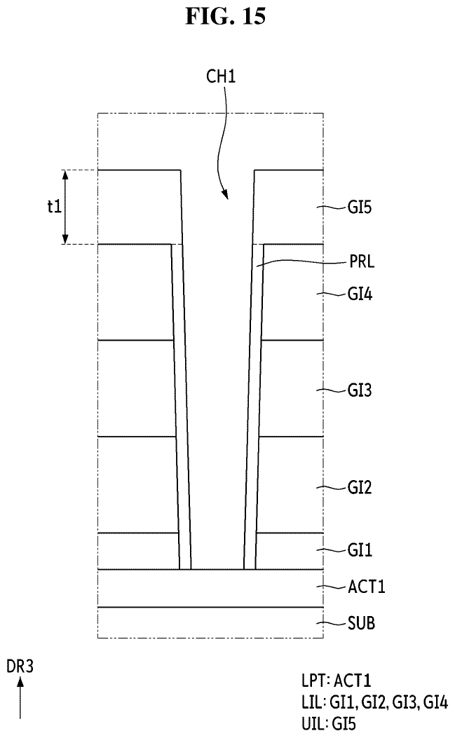

Referring to FIGS. 14 and 15, the first contact hole CH1 may be formed by etching the insulating film GIL to expose a portion of the first active layer ACT1. In one embodiment, the insulating film GIL may be etched by a front-surface anisotropic etching method without using a separate mask pattern. For example, by full-surface anisotropic dry etching (or blanket anisotropic dry etching), a portion of the insulating film GIL covering the lower pattern LPT within the first contact hole CH1 may be removed, and the insulating film GIL may be etched in a perpendicular direction such that another portion of the insulating film GIL remains on the side surface of the lower insulating layer LIL.

A portion of the insulating film GIL remaining on the side surface of the lower insulating layer LIL may be the protective film PRL. For example, the protective film PRL may cover the side surface of the lower insulating layer LIL exposed through the first opening OP1. Another portion of the insulating film GIL remaining on the lower insulating layer LIL may be the upper insulating layer UIL (e.g., the fifth insulating layer GI5). The upper insulating layer UIL may include an opening in communication with the first opening OP1. In some embodiments, after the protective film PRL and the upper insulating layer UIL are formed by full-surface anisotropic dry etching, a post-treatment process including BOE wet etching may be performed in a state where the side surface of the lower insulating layer LIL is covered with the protective film PRL. Accordingly, an undercut may be prevented from occurring at the sidewall of the first contact hole CH1.

In one embodiment, the protective film PRL and the upper insulating layer UIL may be formed integrally. For example, the protective film PRL and the upper insulating layer UIL may be smoothly connected in a continuous manner along the sidewall of the first contact hole CH1.

By etching the insulating film GIL entirely without using a mask pattern, the thickness of the insulating film GIL may be reduced even on the lower insulating layer LIL. For example, the upper insulating layer UIL may have the first thickness t1 that is reduced compared to the third thickness t3.

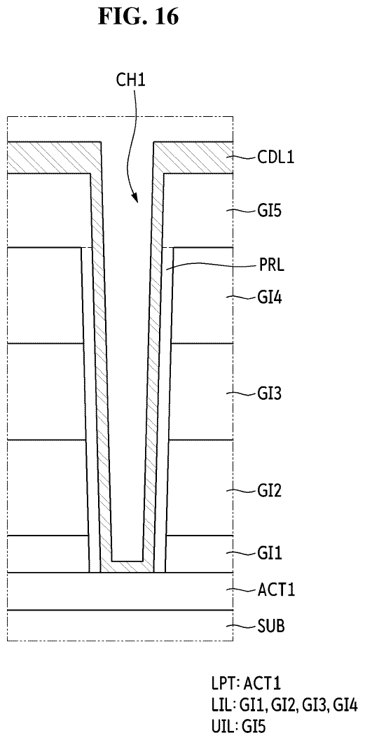

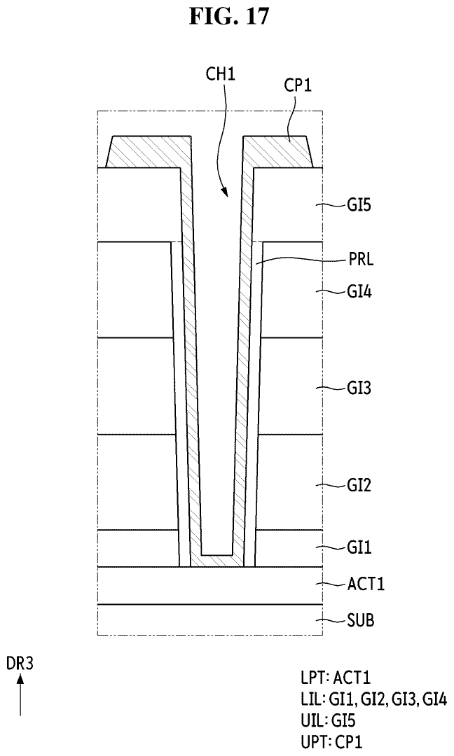

Referring to FIGS. 16 and 17, the upper pattern UPT may be formed on a portion of the lower pattern LPT exposed by the first contact hole CH1, the protective film PRL, and the upper insulating layer UIL. For example, as illustrated in FIG. 16, the conductive film CDL1 may be formed on the lower pattern LPT, the protective film PRL, and the upper insulating layer UIL, and as illustrated in FIG. 17, the conductive film CDL1 may be etched to form the first conductive pattern CP1.

After the formation of the fourth conductive layer GTL4 including the first conductive pattern CP1, a remainder of the circuit layer CRL may be formed by forming the sixth insulating layer GI6, the fifth conductive layer SDL1, the seventh insulating layer ILD1, the sixth conductive layer SDL2, the eighth insulating layer ILD2, the seventh conductive layer SDL3, and the ninth insulating layer VIA, such as those depicted in FIG. 3. Thereafter, the light emitting element layer EDL and the encapsulation layer TFEL of FIG. 3 may be sequentially formed on the circuit layer CRL.

As described above, the display device 10 and the method of manufacturing the same as described in the present disclosure provides many advantages. For example, a contact hole (e.g., the first contact hole CH1) may be formed to connect a lower pattern LPT and upper pattern UPT in a stable manner. Further, in examples where the insulating layers disposed between the pair of lower pattern LPT and upper pattern UPT are distinguished into the lower insulating layer LIL and the upper insulating layer UIL, and the lower insulating layer LIL and the upper insulating layer UIL are sequentially etched through at least two etching processes, the risk (e.g., a risk of un-etching that may occur in the lower insulating layer LIL) of incomplete etching of insulating layers in the contact hole is prevented or at least significantly mitigated. As a result, the lower pattern LPT and the upper pattern UPT may be connected in a stable manner, and the contact quality may be improved.

According to some embodiments, even in examples of the display device 10 with high-resolution that include a contact hole having a narrow width and a deep depth (e.g., a high aspect ratio contact hole such as the first contact hole CH1), the contact hole may be formed in a stable manner, and a lower pattern (e.g., the first active layer ACT1) and an upper pattern (e.g., the first conductive pattern CP1) may be stably connected by the contact hole. Accordingly, a magnitude of depth to which one contact hole may be formed may be increased without an intermediate bridge, and the number and/or size (e.g., width or area) of the contact holes may be reduced or minimized. Accordingly, the design structure of the circuit layer CRL may be improved and/or optimized.

In addition, according to embodiments of the display device 10 and the method of manufacturing the same contemplated by the present disclosure, it is possible to prevent an undercut-shaped stepped portion from occurring at the sidewall of the contact hole in a circuit layer. For example, in some embodiments, a process including BOE wet etching may be performed as a subsequent step where the side surface of the lower insulating layer LIL is in a condition such that the lower insulating layer LIL has been previously etched and is covered with the protective film PRL. Accordingly, the sidewall of the contact hole may have a substantially smooth shape, and the upper pattern UPT may be stably formed inside the contact hole.

As in the embodiments of FIG. 4 and FIGS. 6 to 13, when the width of the contact hole is expanded around the entrance of the contact hole during the formation of the conductive film CDL1 to form the upper pattern UPT filling the contact hole, the entrance of the contact hole may be prevented from being blocked by an overhang before the conductive material is sufficiently deposited inside the contact hole. Accordingly, even when the depth of the contact hole is increased beyond a maximum depth that would otherwise avoid such an overhang condition, the upper pattern UPT may be formed in a stable manner inside the contact hole.

As in the embodiments of FIG. 5 and FIGS. 14 to 17, when the upper insulating layer UIL and the protective film PRL are formed by etching the insulating film GIL without disposing a separate mask pattern onto the insulating film GIL, the process of forming a mask pattern for etching the insulating film GIL may be omitted. Accordingly, the number of mask processes included in the manufacturing process of the display device 10 may be reduced or minimized, and the manufacturing efficiency of manufacturing the display device 10 may be improved.

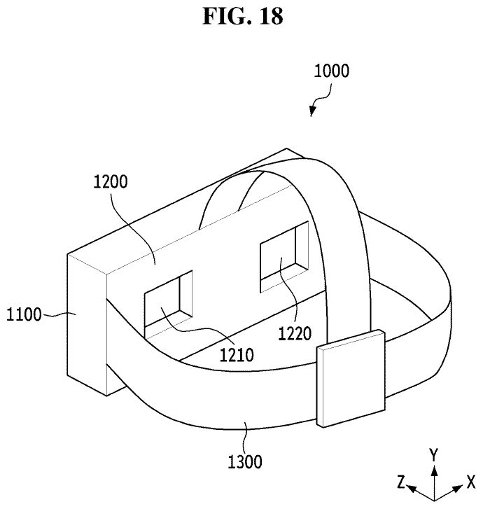

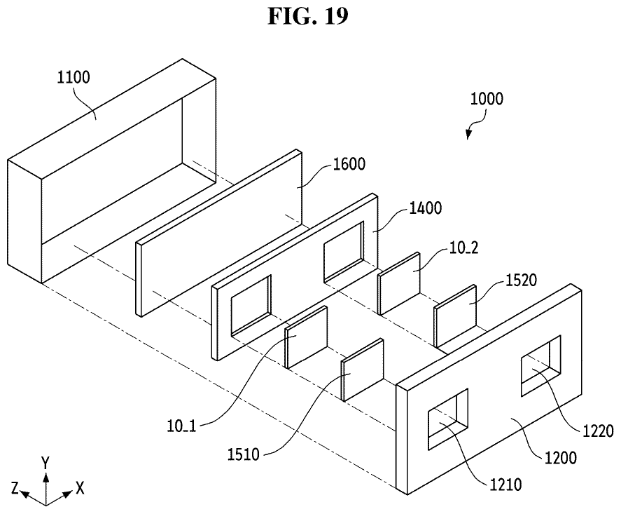

FIG. 18 is a perspective view of a head mounted display according to one embodiment. FIG. 19 is an exploded perspective view of one example of the head mounted display of FIG. 18.

Referring to FIGS. 18 and 19, a head mounted display 1000 according to one embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. In some embodiments, one or both of the first display device 10_1 and the second display device 10_2 may be the display device 10 described in conjunction with FIGS. 1 to 5. In the embodiments described below, both of the first display device 10_1 and the second display device 10_2 are the display device 10. Accordingly, description of the first display device 10_1 and the second display device 10_2 is omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through a connector. The control circuit board 1600 may convert an image source inputted from an external source into digital video data, and transmit the digital video data to the first display device 10_1 and the second display device 10_2 via the connector.

The control circuit board 1600 may transmit the digital video data corresponding to a left-eye image optimized for the user's left eye to the first display device 10_1, and may transmit the digital video data corresponding to a right-eye image optimized for the user's right eye to the second display device 10_2. Alternatively, the control circuit board 1600 may transmit the same digital video data to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. In the head mounted display 1000 depicted in FIGS. 18 and 19, the first eyepiece 1210 and the second eyepiece 1220 are disposed separately, but the embodiments contemplated by the present disclosure are not limited thereto. In some examples, the first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

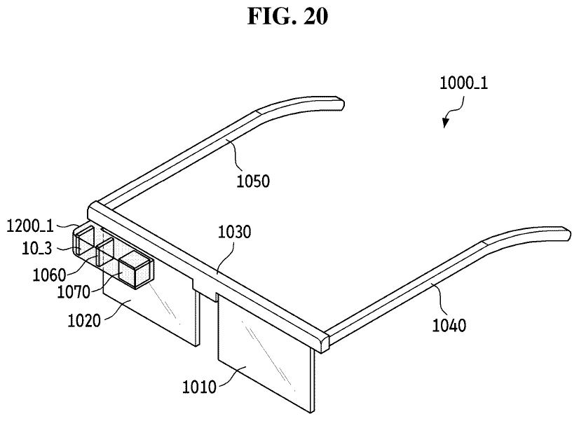

The head mounted band 1300 serves to secure the display device housing 1100 to the user's head such that the first eyepiece 1210 and the second eyepiece 1220 of the housing cover 1200 remain located over the user's left eye and right eye, respectively. When the display device housing 1200 is implemented to be lightweight and compact, the head mounted display 1000 may be provided with, as shown in FIG. 20, an eyeglass frame instead of the head mounted band 1300.

In some embodiments, the head mounted display 1000 may also include one or more of a battery for supplying power, an external memory slot for accommodating an external memory, and an external connection port and a wireless communication module for receiving an image source. The external connection port may be, for example, a universal serial bus (USB) terminal, a display port, or a high-definition multimedia interface (HDMI) terminal, and the wireless communication module may be, for example, a 5G communication module, a 4G communication module, a Wi-Fi module, or a Bluetooth module.

FIG. 20 is a perspective view illustrating a head mounted display according to one embodiment.

Referring to FIG. 20, a head mounted display 1000_1 according to some embodiments may be an eyeglasses-type display device in which a display device housing 1200_1 is implemented in a lightweight and compact manner. The head mounted display 1000_1 according to one embodiment may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 10_3, the optical member 1060, and the optical path conversion member 1070. In some embodiments, the display device 10_3 may be the display device 10 described in conjunction with FIGS. 1 to 5. The image displayed on the display device 10_3 may be magnified by the optical member 1060, and may be provided to the user's right eye through the right eye lens 1020 after the optical path thereof is changed by the optical path conversion member 1070. As a result, the user may view an augmented reality image, through the right eye, in which a virtual image displayed on the display device 10_3 and a real image seen through the right eye lens 1020 are combined.

FIG. 20 illustrates that the display device housing 1200_1 is disposed at the end on the right side of the support frame 1030, but the embodiments contemplated by the present disclosure are not limited thereto. For example, the display device housing 1200_1 may be disposed at the left end of the support frame 1030. In such an arrangement, the image of the display device 10_3 may be provided to the user's left eye. Alternatively, in other examples, the display device housing 1200_1 may be disposed at both the left and right ends of the support frame 1030, and in such an arrangement, the user may view the image displayed on the display device 10_3 through both the left eye and the right eye.

In FIGS. 18 to 20, the head mounted displays 1000 and 1000_1 are illustrated as examples of electronic devices that may include one or more of the display devices 10, 10_1, 10_2, and 10_3, where the display devices may include any number of features contemplated for the display device 10 described herein, but the contemplated electronic device applications of the display device 10 are not limited thereto. For example, the display device 10 described in connection with FIGS. 1 to 5 may be included in an electronic device of a different type or structure other than the head mounted displays 1000 and 1000_1 and, in some examples, may be used as a display screen of the electronic device.

In concluding the detailed description, those skilled in the art will appreciate that many variations and modifications can be made to the embodiments without substantially departing from the principles of the present disclosure. Therefore, the disclosed embodiments of the disclosure are used in a generic and descriptive sense only and not for purposes of limitation.

1. A display device comprising:
a substrate;
a lower pattern disposed on the substrate;
a lower insulating layer disposed on the lower pattern;
an upper insulating layer disposed on the lower insulating layer;
a contact hole penetrating the lower insulating layer and the upper insulating layer, the contact hole exposing a portion of the lower pattern;
a protective film disposed inside the contact hole and covering a side surface of the lower insulating layer; and
an upper pattern disposed on the upper insulating layer and the protective film and connected to the lower pattern through the contact hole.

2. The display device of claim 1, wherein the contact hole comprises a first opening formed in the lower insulating layer and a second opening formed in the upper insulating layer, the first opening and the second opening being in communication with each other, and
a width of the second opening is greater than a width of the first opening.

3. The display device of claim 2, wherein the upper insulating layer and the protective film are spaced apart from each other.

4. The display device of claim 2, wherein the upper pattern has a step-shaped cross-section on a boundary portion between the lower insulating layer and the upper insulating layer.

5. The display device of claim 1, wherein the upper insulating layer and the protective film are directly connected.

6. The display device of claim 1, wherein the upper insulating layer and the protective film are integral.

7. The display device of claim 1, wherein the upper insulating layer and the protective film both include a first material.

8. The display device of claim 1, wherein a thickness of the protective film is less than a thickness of the upper insulating layer.

9. The display device of claim 1, wherein the upper pattern fills at least a portion of the contact hole and is in contact with the lower pattern at a bottom portion of the contact hole.

10. The display device of claim 1, wherein the lower insulating layer is defined by a plurality of insulating layers sequentially stacked on the lower pattern, and
a first insulating layer of the plurality of insulating layers includes a material absent from a second insulating layer of the plurality of insulating layers.

11. The display device of claim 10, wherein the first insulating layer of the plurality of insulating layers includes silicon oxide, and
the second insulating layer of the plurality of insulating layers includes silicon nitride.

12. The display device of claim 10, wherein the protective film covers an entirety of side surfaces of the plurality of insulating layers that define a sidewall portion of the contact hole and exposes the lower pattern at a bottom portion of the contact hole.

13. The display device of claim 1, further comprising:
a circuit layer disposed on the substrate, the circuit layer comprising: the lower pattern, the lower insulating layer, the upper insulating layer, the contact hole, the protective film, the upper pattern, and a circuit element of a pixel; and
a light emitting element layer disposed on the circuit layer, the light emitting element layer comprising: a light emitting element electrically connected to the circuit element.

14. A method of manufacturing a display device, the method comprising:
forming a lower pattern and a lower insulating layer covering the lower pattern on a substrate;
forming a first opening exposing a portion of the lower pattern by etching the lower insulating layer;
forming an insulating film on the lower pattern and the lower insulating layer;
forming a protective film covering a side surface of the lower insulating layer exposed through the first opening and an upper insulating layer disposed on the lower insulating layer by etching the insulating film, the upper insulating layer defining a second opening in communication with the first opening; and
forming an upper pattern connected to the portion of the lower pattern, the protective film, and the upper insulating layer.

15. The method of claim 14, wherein the etching of the insulating film further comprises:
disposing a mask pattern defining an opening onto the insulating film such that when the mask pattern is disposed on the insulating film, the first opening is exposed through the opening defined by the mask pattern; and
etching a portion of the insulating film not covered by the mask pattern.

16. The method of claim 15, wherein disposing the mask pattern onto the insulating film exposes the first opening and the portion of the insulating film positioned around the first opening, the first opening and the portion of the insulating film being exposed through the opening of the mask pattern.

17. The method of claim 16, wherein forming the protective film results in a width of the second opening being larger than a width of the first opening, and
the protective film being spaced apart from the upper insulating layer.

18. The method of claim 14, wherein the etching of the insulating film further comprises removing a portion of the insulating film covering the lower pattern by full-surface anisotropic dry etching.

19. The method of claim 14, further comprising, before the forming of the upper pattern, performing wet etching using a buffered oxide etchant on the side surface of the lower insulating layer covered with the protective film.

20. An electronic device comprising:
a display device comprising:
a substrate;
a lower pattern disposed on the substrate;
a lower insulating layer disposed on the lower pattern;
an upper insulating layer disposed on the lower insulating layer;
a contact hole penetrating the lower insulating layer and the upper insulating layer, the contact hole exposing a portion of the lower pattern;
a protective film disposed inside the contact hole and covering a side surface of the lower insulating layer; and
an upper pattern disposed on the upper insulating layer and the protective film and connected to the lower pattern through the contact hole; and
a display device housing configured to accommodate the display device.
